(19) United States
(12) Patent Application Publication
(10) Pub. No.: US 2026/0190676 A1
(43) Pub. Date: Jul. 2, 2026

(54) Display Substrate and Display Device

(71) Applicants: Chengdu BOE Optoelectronics Technology Co., Ltd., Chengdu, Sichuan (CN); BOE Technology Group Co., Ltd., Beijing (CN)

(72) Inventors: Tiaomei ZHANG, Beijing (CN); Ming HU, Beijing (CN); Zhiliang JIANG, Beijing (CN); Haijun QIU, Beijing (CN); Lang LIU, Beijing (CN); Hongbo MA, Beijing (CN); Mingkun YANG, Beijing (CN); Zhen LIU, Beijing (CN); Jianpeng WU, Beijing (CN); Wenhui GAO, Beijing (CN)

(21) Appl. No.: 18/728,086

(22) PCT Filed: May 31, 2023
(86) PCT No.: PCT/CN2023/097556

§ 371 Date: Jul. 11, 2024

(51) Int. Cl. H10K 59/126; H10K 59/121; H10K 59/131

(52) U.S. Cl. CPC H10K 59/126; H10K 59/1213; H10K 59/131

(57) ABSTRACT

A display substrate and a display device are provided. The display substrate includes a pixel driving circuit, the pixel driving circuit includes a first storage capacitor, a second storage capacitor, at least one shield electrode, and at least one double-gate structured transistor; the first storage capacitor at least includes a first electrode plate (71) and a third electrode plate (73), and an orthographic projection of the first electrode plate (71) on the base substrate at least partially overlaps with an orthographic projection of the third electrode plate (73) on the base substrate; the second storage capacitor at least includes a second electrode plate (72) and a fourth electrode plate (74), and an orthographic projection of the second electrode plate (72) on the base substrate at least partially overlaps with an orthographic projection of the fourth electrode plate (74) on the base substrate.

### CROSS-REFERENCE TO RELATED APPLICATION

The present application is a U.S. National Phase Entry of International Application No. PCT/CN2023/097556 having an international filing date of May 31, 2023. The above-identified application is hereby incorporated by reference.

### TECHNICAL FIELD

The present disclosure relates to, but is not limited to, the field of display technologies, and more particularly, to a display substrate and a display device.

### BACKGROUND

An Organic Light Emitting Diode (OLED for short) and a Quantum dot Light Emitting Diode (QLED for short) are active light emitting display devices and have advantages such as self-luminescence, wide viewing angle, high contrast ratio, low power consumption, very high response speed, lightness and thinness, flexibility, and low cost. With constant development of display technologies, a flexible display device (Flexible Display) in which an OLED or a QLED is used as a light emitting device and signal control is performed through a Thin Film Transistor (TFT for short) has become a mainstream product in the field of display at present.

### SUMMARY

The following is a summary of subject matters described herein in detail. This summary is not intended to limit the protection scope of the claims.

In one aspect, the present disclosure provides a display substrate, including a driving circuit layer provided on a base substrate. The driving circuit layer at least includes a plurality of circuit units, and at least one circuit unit includes a pixel driving circuit including a first storage capacitor, a second storage capacitor, at least one shield electrode, and at least one double-gate structured transistor. The first storage capacitor at least includes a first electrode plate and a third electrode plate, and an orthographic projection of the first electrode plate on the base substrate at least partially overlaps with an orthographic projection of the third electrode plate on the base substrate. The second storage capacitor at least includes a second electrode plate and a fourth electrode plate, and an orthographic projection of the second electrode plate on the base substrate at least partially overlaps with an orthographic projection of the fourth electrode plate on the base substrate. The second electrode plate is connected to the third electrode plate, and the fourth electrode plate is connected to a first power supply line. An orthographic projection of a shield electrode on the base substrate at least partially overlaps with an orthographic projection of a node between two gate electrodes of a double-gate structured transistor on the base substrate.

In an exemplary embodiment, the at least one double-gate structured transistor includes an initialization transistor, a first electrode of the initialization transistor is connected to a first initial signal line, and a second electrode of the initialization transistor is connected to the first electrode plate of the first storage capacitor. The at least one shield electrode includes a first shield electrode connected to the fourth electrode plate, and an orthographic projection of the first shield electrode on the base substrate at least partially overlaps with an orthographic projection of a node between two gate electrodes of the initialization transistor on the base substrate.

In an exemplary embodiment, the fourth electrode plate and the first shield electrode are of an integral structure.

In an exemplary embodiment, the first shield electrode includes a first extension segment and a first shield segment. The first extension segment has a strip shape extending in a second direction, a first end of the first extension segment is connected to the fourth electrode plate, and a second end of the first extension segment is connected to a first end of the first shield segment. The first shield segment has a strip shape extending in a first direction, a first end of the first shield segment is connected to a second end of the first extension segment, and a second end of the first shield segment extends in the first direction. An orthographic projection of the first shield segment on the base substrate at least partially overlaps with an orthographic projection of a node between two gate electrodes of an initialization transistor on the base substrate. The first direction intersects the second direction.

In an exemplary embodiment, the at least one circuit unit further includes at least one first power supply connection line extending in a first direction, the first power supply line has a line shape extending in a second direction, and the first direction intersects the second direction; and the first power supply line is connected to the first power supply connection line to form a mesh structure for transmitting a first power supply signal.

In an exemplary embodiment, the at least one double-gate structured transistor includes an initialization transistor, a first electrode of the initialization transistor is connected to a first initial signal line, and a second electrode of the initialization transistor is connected to the first electrode plate of the first storage capacitor. The at least one shield electrode includes a first shield electrode connected to the first power supply connection line, and an orthographic projection of the first shield electrode on the base substrate at least partially overlaps with an orthographic projection of a node between two gate electrodes of the initialization transistor on the base substrate.

In an exemplary embodiment, the first power supply connection line and the first shield electrode are of an integral structure.

In an exemplary embodiment, the at least one circuit unit further includes a shield connection line connected to the first power supply connection line. The at least one double-gate structured transistor includes an initialization transistor, a first electrode of the initialization transistor is connected to a first initial signal line, and a second electrode of the initialization transistor is connected to the first electrode plate of the first storage capacitor. The at least one shield electrode includes a first shield electrode connected to the shield connection line, and an orthographic projection of the first shield electrode on the base substrate at least partially overlaps with an orthographic projection of a node between two gate electrodes of the initialization transistor on the base substrate.

In an exemplary embodiment, the at least one double-gate structured transistor includes a compensation transistor, and a first electrode of the compensation transistor is connected to the first electrode plate of the first storage capacitor. The at least one shield electrode includes a second shield electrode connected to the fourth electrode plate, and an orthographic projection of the second shield electrode on the base substrate at least partially overlaps with an orthographic projection of a node between two gate electrodes of the compensation transistor on the base substrate.

In an exemplary embodiment, the fourth electrode plate and the second shield electrode are of an integral structure.

In an exemplary embodiment, the second shield electrode includes a second extension segment and a second shield segment. The second extension segment has a strip shape extending in a second direction, a first end of the second extension segment is connected to the fourth electrode plate, and a second end of the second extension segment is connected to a first end of the second shield segment. The second shield segment has a strip shape extending in a first direction, a first end of the second shield segment is connected to a second end of the second extension segment, and a second end of the second shield segment extends in a direction opposite the first direction. An orthographic projection of the second shield segment on the base substrate at least partially overlaps with the orthographic projection of the node between two gate electrodes of the compensation transistor on the base substrate. The first direction intersects the second direction.

In an exemplary embodiment, the at least one double-gate structured transistor includes a compensation transistor, and a first electrode of the compensation transistor is connected to the first electrode plate of the first storage capacitor. The at least one shield electrode includes a second shield electrode connected to the first power supply connection line, and an orthographic projection of the second shield electrode on the base substrate at least partially overlaps with an orthographic projection of a node between two gate electrodes of the compensation transistor on the base substrate.

In an exemplary embodiment, the first power supply connection line and the second shield electrode are of an integral structure.

In an exemplary embodiment, the at least one circuit unit further includes a shield connection line connected to the first power supply connection line. The at least one double-gate structured transistor includes a compensation transistor, and a first electrode of the compensation transistor is connected to the first electrode plate of the first storage capacitor. The at least one shield electrode includes a second shield electrode connected to the shield connection line, and an orthographic projection of the second shield electrode on the base substrate at least partially overlaps with an orthographic projection of a node between two gate electrodes of the compensation transistor on the base substrate.

In an exemplary embodiment, the at least one double-gate structured transistor includes a data writing transistor, a first electrode of the data writing transistor is connected to a data signal line, and a second electrode of the data writing transistor is connected to the second electrode plate of the second storage capacitor. The at least one shield electrode includes a third shield electrode connected to the fourth electrode plate, and an orthographic projection of the third shield electrode on the base substrate at least partially overlaps with an orthographic projection of a node between two gate electrodes of the data writing transistor on the base substrate.

In an exemplary embodiment, the fourth electrode plate and the third shield electrode are of an integral structure.

In an exemplary embodiment, the at least one double-gate structured transistor includes a reference transistor, a first electrode of the reference transistor is connected to a second reference signal line, and a second electrode of the reference transistor is connected to the second electrode plate of the second storage capacitor. The at least one shield electrode includes a fourth shield electrode connected to the fourth electrode plate, and an orthographic projection of the fourth shield electrode on the base substrate at least partially overlaps with an orthographic projection of a node between two gate electrodes of the reference transistor on the base substrate.

In an exemplary embodiment, the fourth electrode plate and the fourth shield electrode are of an integral structure.

In another aspect, the present disclosure further provides a display device, including the display substrate described above.

In another aspect, the present disclosure further provides a display substrate, including a driving circuit layer provided on a base substrate. The driving circuit layer at least includes a plurality of circuit units, and at least one circuit unit includes a pixel driving circuit including a first storage capacitor, a second storage capacitor, at least one shield electrode and at least one double-gate structured transistor. The first storage capacitor at least includes a first electrode plate and a third electrode plate, and the second storage capacitor at least includes a second electrode plate and a fourth electrode plate. An orthographic projection of the shield electrode on the base substrate at least partially overlaps with an orthographic projection of a node between two gate electrodes of a double-gate structured transistor on the base substrate. The at least one double-gate structured transistor includes a first transistor to a ninth transistor, and the pixel driving circuit further includes a first node, a second node, a third node, a fourth node and a fifth node. The first node is respectively connected to a second electrode of the first transistor, a first electrode of the second transistor, a gate electrode of the third transistor and the first electrode plate of the first storage capacitor. The second node is respectively connected to a first electrode of the third transistor, a second electrode of the eighth transistor and a second electrode of the fifth transistor. The third node is respectively connected to a second electrode of the second transistor, a second electrode of the third transistor and a first electrode of the sixth transistor. The fourth node is respectively connected to a second electrode of the sixth transistor and a second electrode of the seventh transistor. The fifth node is respectively connected to a second electrode of the fourth transistor, a second electrode of the ninth transistor, the third electrode plate of the first storage capacitor and the second electrode plate of the second storage capacitor. The fourth electrode plate of the second storage capacitor is connected to a first power supply line.

In another aspect, the present disclosure further provides a display device, including the display substrate described above.

Other aspects of the present disclosure may be comprehended after the drawings and the detailed descriptions are read and understood.

### BRIEF DESCRIPTION OF DRAWINGS

Accompany drawings are used to provide further understanding of technical solution of the present disclosure, and form a part of the description. The accompany drawings and embodiments of the present disclosure are adopted to explain the technical solution of the present disclosure, and do not form limitations on the technical solution of the present disclosure.

FIG. 1 is a schematic diagram of a structure of a display device;

FIG. 2 is a schematic diagram of a planar structure of a display substrate;

FIG. 3 is a schematic diagram of a sectional structure of a display substrate;

FIG. 4 is an equivalent circuit diagram of a pixel driving circuit according to an exemplary embodiment of the present disclosure;

FIG. 5 is a schematic diagram of a planar structure of a display substrate according to an exemplary embodiment of the present disclosure;

FIG. 6 is an enlarged view of regions of the first storage capacitor and the second storage capacitor in FIG. 5;

FIG. 7 is a schematic diagram of a display substrate after a pattern of a semiconductor layer is formed according to the present disclosure;

FIGS. 8A and 8B are schematic diagrams of a display substrate after a pattern of a first conductive layer is formed according to the present disclosure;

FIGS. 9A and 9B are schematic diagrams of a display substrate after a pattern of a second conductive layer is formed according to the present disclosure;

FIG. 10 is a schematic diagram of a display substrate after a pattern of a fourth insulating layer is formed according to the present disclosure;

FIGS. 11A and 11B are schematic diagrams of a display substrate after a pattern of a third conductive layer is formed according to the present disclosure;

FIG. 12 is a schematic diagram of a display substrate after a pattern of a fifth insulating layer is formed according to the present disclosure;

FIGS. 13A and 13B are schematic diagrams of a display substrate after a pattern of a fourth conductive layer is formed according to the present disclosure;

FIG. 14 is a schematic diagram of a planar structure of another display substrate according to an exemplary embodiment of the present disclosure;

FIG. 15a is a schematic diagram of the second conductive layer in FIG. 14;

FIG. 15b is a schematic diagram of the third conductive layer in FIG. 14;

FIG. 16 is a schematic diagram of a planar structure of yet another display substrate according to an exemplary embodiment of the present disclosure;

FIG. 17 is a schematic diagram of the third conductive layer in FIG. 16;

FIG. 18 is an enlarged view of regions of a first storage capacitor and a second storage capacitor in yet another display substrate according to an exemplary embodiment of the present disclosure;

FIG. 19 is an enlarged view of regions of a first storage capacitor and a second storage capacitor in yet another display substrate according to an exemplary embodiment of the present disclosure;

FIG. 20 is an enlarged view of regions of a first storage capacitor and a second storage capacitor in yet another display substrate according to an exemplary embodiment of the present disclosure; and

FIG. 21 is a schematic diagram of a third conductive layer in yet another display substrate according to an exemplary embodiment of the present disclosure.

Reference signs are described as follows.

| | | |
|---|---|---|
| 11-First active layer; | 12-Second active layer; | 13-Third active layer; |
| 14-Fourth active layer; | 15-Fifth active layer; | 16-Sixth active layer; |
| 17-Seventh active layer; | 18-Eighth active layer; | 19-Ninth active layer; |
| 21-First gate electrode; | 22-Second gate electrode; | 24-Fourth gate electrode; |
| 25-Fifth gate electrode; | 26-Sixth gate electrode; | 29-Ninth gate electrode; |
| 31-First light emitting signal line; | 32-Second light emitting signal line; | 33-Repair line; |
| 36-First shield electrode; | 37-Second shield electrode; | 38-Third shield electrode; |
| 39-Fourth shield electrode; | 41-First connection electrode; | 42-Second connection electrode; |
| 43-Third connection electrode; | 44-Fourth connection electrode; | 45-Fifth connection electrode; |
| 46-Sixth connection electrode; | 47-Seventh connection electrode; | 48-Eighth connection electrode; |
| 49-Ninth connection electrode; | 51-First power supply line; | 53-Data signal line; |
| 54-Reference signal connection line; | 55-Anode connection electrode; | 61-First scan signal line; |
| 62-Second scan signal line | 63-Third scan signal line; | 64-Fourth scan signal line; |
| 65-Fifth scan signal line; | 68-First power supply connection line; | 69-Shield connection line; |
| 71-First electrode plate; | 72-Second electrode plate; | 73-Third electrode plate; |
| 74-Fourth electrode plate; | 81-First initial signal line; | 82-Second initial signal line; |
| 91-First reference signal line; | 92-Second reference signal line; | 103-Light emitting structure layer; |
| 101-Base substrate; | 102-driving circuit layer; | 20-Second active connection line. |
| 104-Encapsulation structure layer; | 10-First active connection line; | |

### DETAILED DESCRIPTION

To make the objectives, technical solutions, and advantages of the present disclosure clearer, the embodiments of the present disclosure will be described in detail below with reference to the accompany drawings. It is to be noted that embodiments may be implemented in multiple different forms. Those of ordinary skills in the art can easily understand such a fact that implementation embodiments and contents may be transformed into various forms without departing from the purpose and scope of the present disclosure. Therefore, the present disclosure should not be explained as being limited to the contents recorded in the following embodiments only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of various film layers, and a width and spacing of various signal lines may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals “first”, “second”, “third”, etc., in the specification are set not to form limits in numbers but only to avoid confusion between composition elements.

In the specification, for convenience, expressions “central”, “above”, “below”, “front”, “back”, “vertical”, “horizontal”, “top”, “bottom”, “inside”, “outside”, etc., indicating orientations or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements may be changed as appropriate according to a direction according to which various constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 100 or less, and thus also includes a state in which the angle is −5° or more and 5° or less. In addition, “perpendicular” refers to a state in which an angle formed by two straight lines is 800 or more and 1000 or less, and thus also includes a state in which the angle is 850 or more and 950 or less.

In the specification, a “film” and a “layer” are interchangeable. For example, a “conductive layer” may be replaced with a “conductive film” sometimes. Similarly, an “insulating film” may be replaced with an “insulating layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

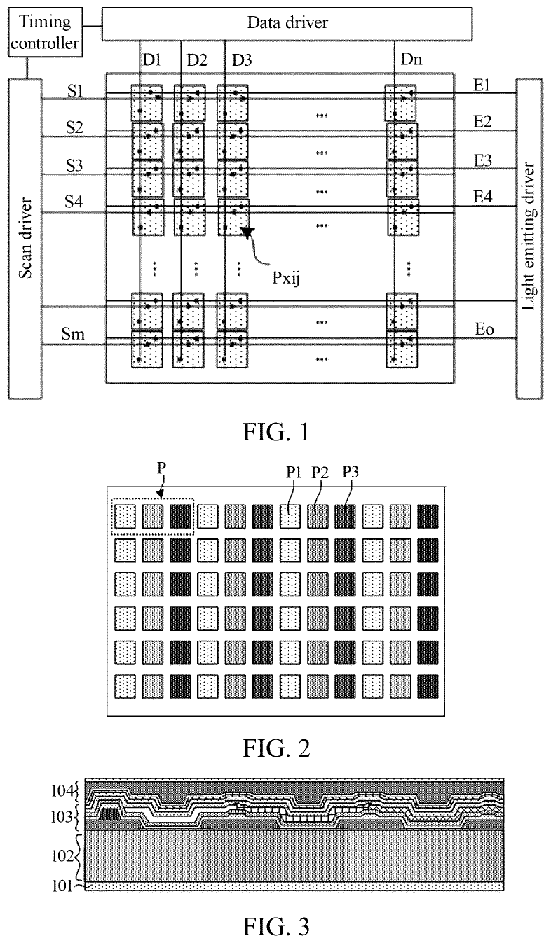

FIG. 1 is a schematic diagram of a structure of a display device. As shown in FIG. 1, the display device may include a timing controller, a data driver, a scan driver, a light emitting driver, and a pixel array. The timing controller is connected to the data driver, the scan driver, and the light emitting driver, respectively, the data driver is connected to a plurality of data signal lines (D1 to Dn) respectively, the scan driver is connected to a plurality of scan signal lines (S1 to Sm) respectively, and the light emitting driver is connected to a plurality of light emitting signal lines (E1 to Eo) respectively. The pixel array may include a plurality of sub-pixels Pxij, i and j may be natural numbers, at least one sub-pixel Pxij may include a circuit unit and a light emitting unit, the circuit unit may include at least a pixel driving circuit connected to a scan signal line, a light emitting signal line and a data signal line, respectively, the light emitting unit may include a light emitting device connected to the pixel driving circuit of the circuit unit. In an exemplary embodiment, the timing controller may provide the data driver with a grayscale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the grayscale value and the control signal that are received from the timing controller. For example, the data driver may sample the grayscale value using the clock signal and apply a data voltage corresponding to the grayscale value to the data signal lines D1 to Dn by taking a pixel row as a unit, wherein n may be a natural number. The scan driver may generate scan signals to be provided to the scan signal lines S1, S2, S3, . . . , and Sm by receiving the clock signal and the scan start signal from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may receive a clock signal, an emission stop signal, etc., from the timing controller to generate an emission signal to be provided to the light emitting signal lines E1, E2, E3, . . . , and Eo. For example, the light emitting driver may sequentially provide an emission signal with an off-level pulse to the light emitting signal lines E1 to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary embodiment, the pixel array may be provided on the display substrate.

FIG. 2 is a schematic diagram of a planar structure of a display substrate. In an exemplary embodiment, the display substrate may include a display area and a bezel area located on a periphery of the display area. As shown in FIG. 2, the display area of the display substrate may include a plurality of pixel units P arranged in a matrix. At least one pixel unit P may include a first sub-pixel P1 emitting light of a first color, a second sub-pixel P2 emitting light of a second color, and a third sub-pixel P3 emitting light of a third color. Each sub-pixel may include a circuit unit and a light emitting unit. The circuit unit may at least include a pixel driving circuit connected to a scan signal line, a data signal line, and a light emitting signal line, respectively. The pixel driving circuit is configured to receive a data voltage transmitted by the data signal line and output a corresponding current to the light emitting device under control of the scan signal line and the light emitting signal line. The light emitting unit may at least include a light emitting device connected to a pixel driving circuit of a sub-pixel where the light emitting device is located. The light emitting device is configured to emit light of a corresponding brightness in response to a current output by the pixel driving circuit of the sub-pixel where the light emitting device is located.

In an exemplary embodiment, the first sub-pixel P1 may be a red (R) sub-pixel emitting red light, the second sub-pixel P2 may be a blue (B) sub-pixel emitting blue light, and the third sub-pixel P3 may be a green (G) sub-pixel emitting green light. In an exemplary embodiment, the sub-pixel may be in a shape of a rectangle, a rhombus, a pentagon, or a hexagon. Three sub-pixels may be arranged in a manner to stand side by side horizontally, in a manner to stand side by side vertically, or in a manner like a Chinese character “A”, etc., which is not limited here in the present disclosure.

In an exemplary embodiment, a pixel unit may include four sub-pixels, and the four sub-pixels may be arranged in a manner to stand side by side horizontally, in a manner to stand side by side vertically, or in a manner to form a square, which is not limited here in the present disclosure.

FIG. 3 is a schematic diagram of a sectional structure of a display substrate, and illustrates a structure of three sub-pixels in the display substrate. As shown in FIG. 3, on a plane perpendicular to the display substrate, the display area of the display substrate may include a driving circuit layer 102 provided on a base substrate 101, a light emitting structure layer 103 provided on a side of the driving circuit layer 102 away from the base substrate 101, and an encapsulation structure layer 104 provided on a side of the light emitting structure layer 103 away from the base substrate 101. In some possible embodiments, the display substrate may include other films, such as a touch structure layer, which is not limited here in the present disclosure.

In an exemplary embodiment, the base substrate 101 may be a flexible base substrate, or may be a rigid base substrate. The driving circuit layer 102 may include a plurality of circuit units, a circuit unit may at least include a pixel driving circuit, and the pixel driving circuit may include a plurality of transistors and a storage capacitor. The light emitting structure layer 103 may include a plurality of light emitting units, a light emitting unit may at least include a light emitting device, and the light emitting device may include an anode, an organic emitting layer, and a cathode. The anode is connected to the pixel driving circuit. The organic emitting layer is connected to the anode. The cathode is connected to the organic emitting layer. The organic emitting layer emits light of a corresponding color under driving of the anode and the cathode. The encapsulation layer 104 may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is provided between the first encapsulation layer and the third encapsulation layer to form a laminated structure of an inorganic material/an organic material/an inorganic material to ensure that external water vapor cannot enter the light emitting structure layer 103.

In an exemplary embodiment, the organic emitting layer may include an Emitting Layer (EML), and any one or more of following layers: a Hole Injection Layer (HIL), a Hole Transport Layer (HTL), an Electron Block Layer (EBL), a Hole Block Layer (HBL), an Electron Transport Layer (ETL), and an Electron Injection Layer (EIL).

An exemplary embodiment of the present disclosure provides a display substrate, including a driving circuit layer provided on a base substrate. The driving circuit layer at least includes a plurality of circuit units, and at least one circuit unit includes a pixel driving circuit including a first storage capacitor, a second storage capacitor, at least one shield electrode, and at least one double-gate structured transistor. The first storage capacitor at least includes a first electrode plate and a third electrode plate, and an orthographic projection of the first electrode plate on the base substrate at least partially overlaps with an orthographic projection of the third electrode plate on the base substrate. The second storage capacitor at least includes a second electrode plate and a fourth electrode plate, and an orthographic projection of the second electrode plate on the base substrate at least partially overlaps with an orthographic projection of the fourth electrode plate on the base substrate. The second electrode plate is connected to the third electrode plate, and the fourth electrode plate is connected to a first power supply line. An orthographic projection of a shield electrode on the base substrate at least partially overlaps with an orthographic projection of a node between two gate electrodes of a double-gate structured transistor on the base substrate.

In an exemplary embodiment, the at least one double-gate structured transistor includes an initialization transistor, a first electrode of the initialization transistor is connected to a first initial signal line, and a second electrode of the initialization transistor is connected to the first electrode plate of the first storage capacitor. The at least one shield electrode includes a first shield electrode connected to the fourth electrode plate, and an orthographic projection of the first shield electrode on the base substrate at least partially overlaps with an orthographic projection of a node between two gate electrodes of the initialization transistor on the base substrate.

In an exemplary embodiment, the at least one double-gate structured transistor includes an initialization transistor, a first electrode of the initialization transistor is connected to a first initial signal line, and a second electrode of the initialization transistor is connected to the first electrode plate of the first storage capacitor. The at least one shield electrode includes a first shield electrode connected to the first power supply connection line, and an orthographic projection of the first shield electrode on the base substrate at least partially overlaps with an orthographic projection of a node between two gate electrodes of the initialization transistor on the base substrate.

In an exemplary embodiment, the at least one circuit unit further includes a shield connection line connected to the first power supply connection line. The at least one double-gate structured transistor includes an initialization transistor, a first electrode of the initialization transistor is connected to a first initial signal line, and a second electrode of the initialization transistor is connected to the first electrode plate of the first storage capacitor. The at least one shield electrode includes a first shield electrode connected to the shield connection line, and an orthographic projection of the first shield electrode on the base substrate at least partially overlaps with an orthographic projection of a node between two gate electrodes of the initialization transistor on the base substrate.

In an exemplary embodiment, the at least one double-gate structured transistor includes a compensation transistor, and a first electrode of the compensation transistor is connected to the first electrode plate of the first storage capacitor. The at least one shield electrode includes a second shield electrode connected to the fourth electrode plate, and an orthographic projection of the second shield electrode on the base substrate at least partially overlaps with an orthographic projection of a node between two gate electrodes of the compensation transistor on the base substrate.

In an exemplary embodiment, the second shield electrode includes a second extension segment and a second shield segment. The second extension segment has a strip shape extending in a second direction, a first end of the second extension segment is connected to the fourth electrode plate, and a second end of the second extension segment is connected to a first end of the second shield segment. The second shield segment has a strip shape extending in a first direction, a first end of the second shield segment is connected to a second end of the second extension segment, and a second end of the second shield segment extends in a direction opposite the first direction. An orthographic projection of the second shield segment on the base substrate at least partially overlaps with the orthographic projection of the node between two gate electrodes of the compensation transistor on the base substrate. The first direction intersects the second direction.

In an exemplary embodiment, the at least one double-gate structured transistor includes a compensation transistor, and a first electrode of the compensation transistor is connected to the first electrode plate of the first storage capacitor. The at least one shield electrode includes a second shield electrode connected to the first power supply connection line, and an orthographic projection of the second shield electrode on the base substrate at least partially overlaps with an orthographic projection of a node between two gate electrodes of the compensation transistor on the base substrate.

In an exemplary embodiment, the at least one circuit unit further includes a shield connection line connected to the first power supply connection line. The at least one double-gate structured transistor includes a compensation transistor, and a first electrode of the compensation transistor is connected to the first electrode plate of the first storage capacitor. The at least one shield electrode includes a second shield electrode connected to the shield connection line, and an orthographic projection of the second shield electrode on the base substrate at least partially overlaps with an orthographic projection of a node between two gate electrodes of the compensation transistor on the base substrate.

In an exemplary embodiment, the at least one double-gate structured transistor includes a data writing transistor, a first electrode of the data writing transistor is connected to a data signal line, and a second electrode of the data writing transistor is connected to the second electrode plate of the second storage capacitor. The at least one shield electrode includes a third shield electrode connected to the fourth electrode plate, and an orthographic projection of the third shield electrode on the base substrate at least partially overlaps with an orthographic projection of a node between two gate electrodes of the data writing transistor on the base substrate.

In an exemplary embodiment, the at least one double-gate structured transistor includes a reference transistor, a first electrode of the reference transistor is connected to a second reference signal line, and a second electrode of the reference transistor is connected to the second electrode plate of the second storage capacitor. The at least one shield electrode includes a fourth shield electrode connected to the fourth electrode plate, and an orthographic projection of the fourth shield electrode on the base substrate at least partially overlaps with an orthographic projection of a node between two gate electrodes of the reference transistor on the base substrate.

The display substrate of the present disclosure is illustrated with examples below through some exemplary embodiments.

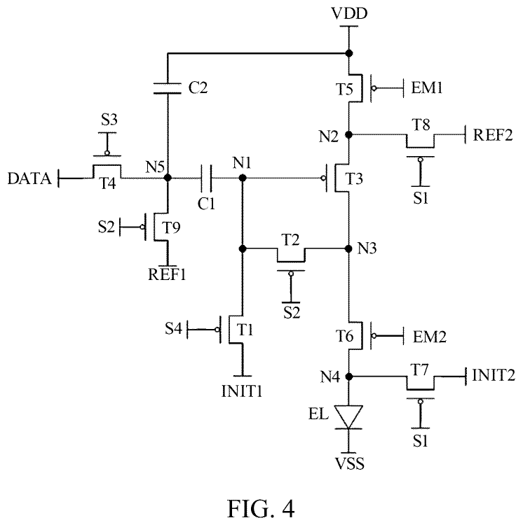

FIG. 4 is an equivalent circuit diagram of a pixel driving circuit according to an exemplary embodiment of the present disclosure. In some exemplary embodiments, the pixel driving circuit may have a structure of 3T1C, 4T1C, 5T1C, 5T2C, 6T1C, 7T1C, 8T1C or 9T2C.

As shown in FIG. 4, the pixel driving circuit of the exemplary embodiment of the present disclosure may be of a 9T2C structure and may include nine transistors (a first transistor T1 to a ninth transistor T9) and two storage capacitors (a first storage capacitor C1 and a second storage capacitor C2), and the pixel driving circuit is respectively connected to 12 signal lines (first scan signal line S1, second scan signal line S2, third scan signal line S3, fourth scan signal line S4, first light emitting signal line EM1, second light emitting signal line EM2, first initial signal line INIT1, second initial signal line INIT2, first reference signal line REF1, second reference signal line REF2, DATA signal line DATA and first power supply line VDD).

In an exemplary embodiment, the pixel driving circuit may include a first node N1, a second node N2, a third node N3, a fourth node N4, and a fifth node N5. The first node N1 is respectively connected to a second electrode of the first transistor, a first electrode of the second transistor T2, a gate electrode of the third transistor T3 and a first end of the first storage capacitor C1. The second node N2 is respectively connected to a first electrode of the third transistor T3, a second electrode of the eighth transistor T8 and a second electrode of the fifth transistor T5. The third node N3 is respectively connected to a second electrode of the second transistor T2, a second electrode of the third transistor T3 and a first electrode of the sixth transistor T6. The fourth node N4 is respectively connected to a second electrode of the sixth transistor T6 and a second electrode of the seventh transistor T7. The fifth node N5 is respectively connected to a second electrode of the fourth transistor T4, a second electrode of the ninth transistor T9, a second end of the first storage capacitor C1 and a second end of the second storage capacitor C2.

In an exemplary embodiment, the first end (lower electrode plate) of the first storage capacitor C1 is connected to the first node N1, the second end (upper electrode plate) of the first storage capacitor C1 is connected to the fifth node N5, the first end (upper electrode plate) of the second storage capacitor C2 is connected to the first power supply line VDD, and the second end (lower electrode plate) of the second storage capacitor C2 is connected to the fifth node N5.

In an exemplary embodiment, a gate electrode of the first transistor T1 is connected to the fourth scan signal line S4. When a turn-on signal is applied to the fourth scan signal line S4, the first transistor T1 transmits a first initial voltage to a gate electrode of the third transistor T3 and the first end of the first storage capacitor C1 to release the accumulated charge in the first storage capacitor C1 and achieve initialization. The first transistor T1 may be referred to as a first initialization transistor.

In an exemplary embodiment, a gate electrode of the second transistor T2 is connected to the second scan signal line S2, a first electrode of the second transistor T2 is connected to the first node N1, and a second electrode of the second transistor T2 is connected to the third node N3. When a turn-on signal is applied to the second scan signal line S2, the second transistor T2 enables the gate electrode of the third transistor T3 to be connected to the second electrode of the third transistor T3. The second transistor T2 may be referred to as a compensation transistor.

In an exemplary embodiment, a gate electrode of the third transistor T3 is connected to the first node N1, i.e., the gate electrode of the third transistor T3 is connected to the first end of the first storage capacitor C1, a first electrode of the third transistor T3 is connected to the second node N2, and a second electrode of the third transistor T3 is connected to the third node N3. The third transistor T3 determines a magnitude of a driving current according to a potential difference between the gate electrode and the first electrode thereof. The third transistor T3 may be referred to as a drive transistor.

In an exemplary embodiment, a gate electrode of the fourth transistor T4 is connected to the third scan signal line S3, a first electrode of the fourth transistor T4 is connected to the data signal line DATA, and the second electrode of the fourth transistor T4 is connected to the fifth node N5. When a turn-on signal is applied to the third scan signal line S3, the fourth transistor T4 inputs a data voltage of the data signal line DATA to the second end of the first storage capacitor C1 and the second end of the second storage capacitor C2. The fourth transistor T4 may be referred to as a data writing transistor.

In an exemplary embodiment, a gate electrode of the fifth transistor T5 is connected to the first light emitting signal line EM1, a first electrode of the fifth transistor T5 is connected to the first power supply line VDD, and a second electrode of the fifth transistor T5 is connected to the second node N2. A gate electrode of the sixth transistor T6 is connected to the second light emitting signal line EM2, a first electrode of the sixth transistor T6 is connected to the third node N3, and a second electrode of the sixth transistor T6 is connected to the fourth node N4. When a turn-on signal is applied to the first light emitting signal line EM1 and the second light emitting signal line EM2, the fifth transistor T5 and the sixth transistor T6 form a drive current path between the first power supply line VDD and the second power supply line VSS to enable the light emitting device EL to emit light. The fifth transistor T5 may be referred to as a first light emitting writing transistor. The sixth transistor T6 may be referred to as a second light emitting writing transistor

In an exemplary embodiment, a gate electrode of the seventh transistor T7 is connected to the first scan signal line S1, a first electrode of the seventh transistor T7 is connected to the second initial signal line INIT2, and a second electrode of the seventh transistor T7 is connected to the fourth node N4. When a turn-on signal is applied to the first scan signal line S1, the seventh transistor T7 transmits a second initial voltage to a first electrode of the light emitting device EL, so as to release the accumulated charge in the first electrode of the light emitting device EL and achieve initialization. The seventh transistor T7 may be referred to as a second initialization transistor.

In an exemplary embodiment, a gate electrode of the eighth transistor T8 is connected to the first scan signal line S1, a first electrode of the eighth transistor T8 is connected to the second reference signal line REF2, and a second electrode of the eighth transistor T8 is connected to the second node N2. When a turn-on signal is applied to the first scan signal line S1, the eighth transistor T8 transmits a second reference signal to the second node N2. The eighth transistor T8 may be referred to as a second reference transistor.

In an exemplary embodiment, a gate electrode of the ninth transistor T9 is connected to the second scan signal line S2, a first electrode of the ninth transistor T9 is connected to the first reference signal line REF1, and a second electrode of the ninth transistor T9 is connected to the fifth node N5. When a turn-on signal is applied to the second scan signal line S2, the ninth transistor T9 transmits a first reference signal to the fifth node N5. The ninth transistor T9 may be referred to as a first reference transistor.

In an exemplary embodiment, the light emitting device EL may be an OLED including a first electrode (anode), an organic light emitting layer, and a second electrode (cathode) which are stacked, or may be a QLED including a first electrode (anode), a quantum dot light emitting layer, and a second electrode (cathode) which are stacked. A first electrode of the light emitting device EL is connected to the fourth node N4, and a second electrode of the light emitting device EL is connected to the second power supply line VSS. A signal of the second power supply line VSS is a continuously supplied low-level signal, and a signal of the first power supply line VDD is a continuously supplied high-level signal.

In an exemplary embodiment, the first transistor T1 to the ninth transistor T9 may be P-type transistors, or may be N-type transistors. Use of the same type of transistors in a pixel driving circuit may simplify a process flow, reduce a process difficulty of a display panel, and improve a product yield. In some possible embodiments, the first transistor T1 to the ninth transistor T9 may include P-type transistor(s) and N-type transistor(s).

In an exemplary embodiment, the first transistor T1 to the ninth transistor T9 may adopt low-temperature polysilicon thin film transistors, or may adopt oxide thin film transistors, or may adopt both low-temperature polysilicon thin film transistors and oxide thin film transistors. An active layer of a low temperature poly silicon thin film transistor may be made of Low Temperature Poly silicon (LTPS for short), and an active layer of an oxide thin film transistor may be made of an oxide semiconductor (Oxide). The low temperature poly silicon thin film transistor has advantages, such as a high mobility and fast charging, and the oxide thin film transistor has advantages, such a low drain current. The low temperature poly silicon thin film transistor and the oxide thin film transistor are integrated on one display substrate, that is a LTPS+Oxide (LTPO for short) display substrate, so that advantages of the low temperature poly silicon thin film transistor and the oxide thin film transistor may be utilized, low-frequency drive may be achieved, power consumption may be reduced, and display quality may be improved.

In an exemplary embodiment, an operation process of the pixel driving circuit shown in FIG. 4 may include a first stage to a fifth stage.

First stage: The first stage may include a plurality of sub-stages that are repeatedly executed, and each sub-stage may include a first sub-stage and a second sub-stage that are sequentially executed.

In the first sub-stage, signals of the fourth scan signal line S4 and the first light emitting signal line EM1 are turn-on signals, and signals of the other signal lines are turn-off signals. The signal of the fourth scan signal line S4 is a turn-on signal so that the first transistor T1 is turned on, and a first initial signal of the first initial signal line INIT1 may be supplied to the first node N1 to initialize the first node N1. When the third transistor T3 is a P-type transistor, the third transistor T3 is turned on. The turn-on signal of the first light emitting signal line EM1 may cause the fifth transistor T5 to be turned on, and a first power supply signal of the first power supply line VDD may be supplied to the second node N2.

In the second sub-stage, signals of the second scan signal line S2 and the first light emitting signal line EM1 are turn-on signals, and signals of the other signal lines are turn-off signals. The signal of the second scan signal line S2 is a turn-on signal so that the second transistor T2 is turned on, the first node N1 and the third node N3 are connected, and a threshold voltage of the third transistor T3 is written into the first node N1. The signal of the second scan signal line S2 is a turn-on signal so that the ninth transistor T9 is turned on, and a first reference signal of the first reference signal line REF1 is supplied to the fifth node N5 to initialize the fifth node N5. The turn-on signal of the first light emitting signal line EM1 may cause the fifth transistor T5 to be turned on, and the first power supply signal of the first power supply line VDD may be supplied to the second node N2.

Second stage: A signal of the third scan signal line S3 is a turn-on signal, and signals of the other signal lines are turn-off signals. The signal of the third scan signal line S3 is a turn-on signal so that the fourth transistor T4 is turned on, and a data voltage supplied by the data signal line DATA is written into the fifth node N5.

Third stage: A signal of the first scan signal line S1 is a turn-on signal, and signals of the other signal lines are turn-off signals. The signal of the first scan signal line S1 is a turn-on signal so that the seventh transistor T7 is turned on, and a second initial signal of the second initial signal line INIT2 may be written into the fourth node N4 to initialize the fourth node N4, so as to prevent a residual signal of the previous frame from affecting the display of the current frame. The signal of the first scan signal line S1 is a turn-on signal so that the eighth transistor T8 is turned on, and a second reference signal of the second reference signal line REF2 may be written into the second node N2.

Fourth stage: A signal of the second light emitting signal line EM2 is a turn-on signal, and signals of the other signal lines are turn-off signals. The signal of the second light emitting signal line EM2 is a turn-on signal so that the sixth transistor T6 is turned on, and the third node N3 and the fourth node N4 are connected so that potentials of the third node N3 and the fourth node N4 are the same.

Fifth stage: Signals of the first light emitting signal line EM1 and the second light emitting signal line EM2 are turn-on signals, and signals of the other signal lines are turn-off signals. The signals of the first light emitting signal line EM1 and the second light emitting signal line EM2 are turn-on signals so that the fifth transistor T5 and the sixth transistor T6 are turned on, and a first power supply signal of the first power supply line VDD may provide a driving signal to the light emitting device EL through the fifth transistor T5, the third transistor T3 and the sixth transistor T6 which are turned on, so as to drive the light emitting device EL to emit light.

In an exemplary embodiment, because the drive transistor (i.e., the third transistor T3) is in a state for a long time, electrons are caught in traps, resulting in hysteresis. Thus, in the first stage, by initializing the first node N1 and writing the threshold voltage into the first node N1 multiple times (for example, three times), not only the hysteresis of the drive transistor may be reduced, but also the potential stability of the first node N1 may be ensured. In the third stage, the second reference signal is written into the second node N2. By changing a potential of the second node N2, the hysteresis of the drive transistor may be reduced. In the fourth stage, by connecting the third node N3 and the fourth node N4, the potential of the fourth node N4 may be increased, which is beneficial to reduce the time required to reach the onset voltage of the light emitting device.

The pixel driving circuit provided by the present disclosure may effectively improve the hysteresis of the drive transistor, and thus is beneficial to improving the display effect.

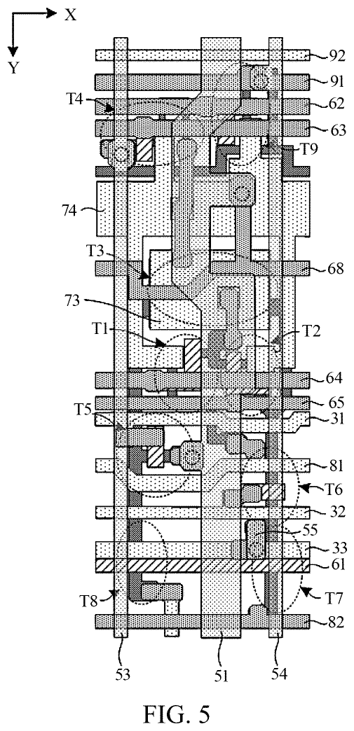

FIG. 5 is a schematic diagram of a planar structure of a display substrate according to an exemplary embodiment of the present disclosure, illustrating a structure of a pixel driving circuit in one circuit unit in a display substrate. In an exemplary embodiment, the display substrate may include a driving circuit layer provided on a substrate and a light emitting structure layer provided on a side of the driving circuit layer away from the base substrate. The driving circuit layer may at least include a plurality of circuit units, and the light emitting structure layer at least includes a plurality of light emitting units. At least one circuit unit includes a pixel driving circuit, and at least one light emitting unit includes a light emitting device. The light emitting device may at least include an anode, an organic light emitting layer, and a cathode. The anode in a light emitting unit is connected to the pixel driving circuit in a corresponding circuit unit. In an exemplary embodiment, the circuit units mentioned in the present disclosure refer to regions divided according to pixel driving circuits, and light emitting units mentioned in the present disclosure refer to regions divided according to light emitting devices. In an exemplary embodiment, a position of an orthographic projection of a light emitting unit on the base substrate may correspond to a position of an orthographic projection of a circuit unit on the base substrate, or a position of an orthographic projection of a light emitting unit on the base substrate may not correspond to a position of an orthographic projection of a circuit unit on the base substrate.

In an exemplary embodiment, a plurality of circuit units sequentially provided in a first direction X may be referred to as a unit row, and a plurality of circuit units sequentially provided in a second direction Y may be referred to as a unit column. A plurality of unit rows and a plurality of unit columns form a circuit unit array in which the circuit units are arranged in an array. The first direction X intersects the second direction Y. For example, the first direction X is perpendicular to the second direction Y.

As shown in FIG. 5, in an exemplary embodiment, the driving circuit layer may further include at least one first power supply line 51 extending in the second direction Y and at least one first power supply connection line 68 extending in the first direction X. In an exemplary embodiment, the first power supply line 51 is connected to pixel driving circuits in the plurality of circuit units and is configured to continuously supply a high-level signal to the pixel driving circuits. In an exemplary embodiment, the first power supply line 51 extending in the second direction Y and the first power supply connection line 68 extending in the first direction X are connected to each other to form a mesh structure for transmitting a power supply signal.

In the present disclosure, A being extended along a B direction means that A may include a main portion and a secondary portion connected to the main portion, the main portion is a line, a line segment, or a strip-shaped body, the main portion extends along the B direction, and a length of the main portion extends along the B direction is greater than a length of the secondary portion extends along another direction.

In an exemplary embodiment, the driving circuit layer may further include a reference signal connection line 54 having a line shape extending in the second direction Y and a first reference signal line 91 having a line shape extending in the first direction X, and the reference signal connection line 54 and the first reference signal line 91 are connected to each other to form a mesh structure for transmitting a first reference signal.

In an exemplary embodiment, on a plane perpendicular to the display substrate, the driving circuit layer may include a semiconductor layer, a first conductive layer, a second conductive layer, a third conductive layer and a fourth conductive layer that are sequentially provided on the base substrate. The first power supply line 51 and the first power supply connection line 68 may be provided in different conductive layers and may be connected through a via.

In an exemplary embodiment, the first power supply connection line 68 may be provided in the third conductive layer, and the first power supply line 51 may be provided in the fourth conductive layer.

In an exemplary embodiment, a reference signal connection line 54 and a first reference signal line 91 may be provided in different conductive layers and may be connected through a via.

In an exemplary embodiment, the first reference signal line 91 may be provided in the third conductive layer, and the reference signal connection line 54 may be provided in the fourth conductive layer.

In an exemplary embodiment, at least one pixel driving circuit may include a first transistor T1 as a first initialization transistor, a second transistor T2 as a compensation transistor, a third transistor T3 as a drive transistor, a fourth transistor T4 as a data writing transistor, a fifth transistor T5 as a first light emitting transistor, a sixth transistor T6 as a second light emitting transistor, a seventh transistor T7 as a second initialization transistor, an eighth transistor T8 as a second reference transistor, a ninth transistor T9 as a first reference transistor, a first storage capacitor and a second storage capacitor.

In an exemplary embodiment, a gate electrode of the first transistor T1 is connected to a fourth scan signal line 64, a first electrode of the first transistor T1 is connected to a first initial signal line 81, and a second electrode of the first transistor T1 is respectively connected to a first electrode of the second transistor T2 and a first electrode plate 71 of the first storage capacitor. A gate electrode of the second transistor T2 is connected to a fifth scan signal line 65, and a second electrode of the second transistor T2 is respectively connected to a second electrode of the third transistor T3 and a first electrode of the sixth transistor T6. A gate electrode of the third transistor T3 serves as the first electrode plate 71 of the first storage capacitor, and a first electrode of the third transistor T3 is respectively connected to a second electrode of the fifth transistor T5 and a second electrode of the eighth transistor T8. A gate electrode of the fourth transistor T4 is connected to a third scan signal line 63, a first electrode of the fourth transistor T4 is connected to a data signal line 53, and a second electrode of the fourth transistor T4 is respectively connected to a second electrode of the ninth transistor T9, a third electrode plate 73 of the first storage capacitor and a second electrode plate 72 of the second storage capacitor. A gate electrode of the fifth transistor T5 is connected to a first light emitting signal line 31, and a first electrode of the fifth transistor T5 is connected to the first power supply line 51. A gate electrode of the sixth transistor T6 is connected to a second light emitting signal line 32, and a second electrode of the sixth transistor T6 is connected to a second electrode of the seventh transistor T7. A gate electrode of the seventh transistor T7 is connected to a first scan signal line 61, and a first electrode of the seventh transistor T7 is connected to a second initial signal line 82. A gate electrode of the eighth transistor T8 is connected to the first scan signal line 61, and a first electrode of the eighth transistor T8 is connected to a second reference signal line 92. A gate electrode of the ninth transistor T9 is connected to a second scan signal line 62, and a first electrode of the ninth transistor T9 is connected to a first reference signal line 91.

In an exemplary embodiment, the second scan signal line 62 and the fifth scan signal line 65 transmit the same scan signal.

In an exemplary embodiment, the first scan signal line 61, the second scan signal line 62, the third scan signal line 63, the fourth scan signal line 64, the fifth scan signal line 65, the first light emitting signal line 31, the second light emitting signal line 32, the first initial signal line 81, the second initial signal line 82, the first reference signal line 91, and the second reference signal line 92 may each have a line shape in which a main body portion extends in the first direction X, and the first power supply line 51 and the data signal line 53 may each have a line shape in which a main body portion extends in the second direction Y.

In an exemplary embodiment, at least one circuit unit may further include an anode connection electrode 55 connected to the second electrode of the sixth transistor T6 and the second electrode of the seventh transistor T7, respectively on the one hand, and on the other hand connected to the anode of the light emitting unit.

In an exemplary embodiment, the driving circuit layer may further include a repair line 33 having a line shape in which a main body portion extends in the first direction X. An orthographic projection of the repair line 33 on the base substrate at least partially overlaps an orthographic projection of the anode connection electrode 55 on the base substrate. The repair line 33 is configured so that when a bright spot defect occurs on the display substrate, a signal is input to an anode of a sub-pixel having the bright spot defect through the repair line 33, to repair it into a dark spot.

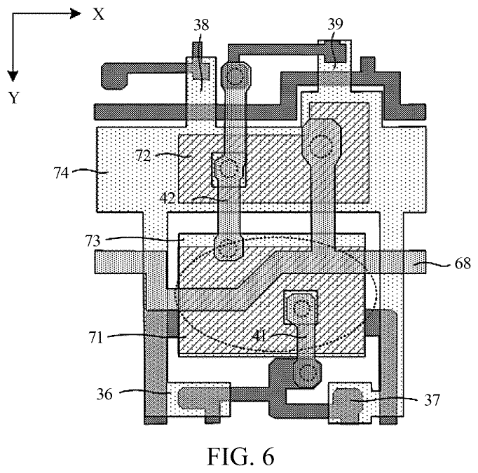

FIG. 6 is an enlarged view of regions of the first storage capacitor and the second storage capacitor in FIG. 5. As shown in FIGS. 5 and 6, in an exemplary embodiment, the first storage capacitor may at least include a first electrode plate 71 and a third electrode plate 73, and an orthographic projection of the third electrode plate 73 on the base substrate at least partially overlaps with an orthographic projection of the first electrode plate 71 on the base substrate.

The second storage capacitor may at least include a second electrode plate 72 and a fourth electrode plate 74, and an orthographic projection of the fourth electrode plate 74 on the base substrate at least partially overlaps with an orthographic projection of the second electrode plate 72 on the base substrate.

In an exemplary embodiment, the first electrode plate 71 and the second electrode plate 72 may be provided in the first conductive layer, and the third electrode plate 73 and the fourth electrode plate 74 may be provided in the second conductive layer. The first electrode plate 71 may serve as a gate electrode of the third transistor T3, the second electrode plate 72 is connected to the third electrode plate 73, and the fourth electrode plate 74 is connected to the first power supply line 51.

As shown in FIGS. 5 and 6, in an exemplary embodiment, at least one circuit unit may further include a first connection electrode 41 connected to a second electrode of the first transistor T1, a first electrode of the second transistor T2, and the first electrode plate 71 of the first storage capacitor, respectively. The first connection electrode 41 may serve as a first node N1 of the pixel driving circuit.

In an exemplary embodiment, the at least one circuit unit may further include a second connection electrode 42 connected to a second electrode of the fourth transistor T4, a second electrode of the ninth transistor T9, the third electrode plate 73 of the first storage capacitor, and the second electrode plate 72 of the second storage capacitor, respectively. The second connection electrode 42 may serve as a fifth node N5 of the pixel driving circuit.

In an exemplary embodiment, an orthographic projection of the first power supply line 51 on the base substrate at least partially overlaps with an orthographic projection of the second connection electrode 42 on the base substrate to shield the influence of other signals in the pixel driving circuit on the fifth node.

In an exemplary embodiment, the at least one circuit unit may further include a first shield electrode 36 connected to the fourth electrode plate 74, and an orthographic projection of the first shield electrode 36 on the base substrate at least partially overlaps with an orthographic projection of a semiconductor layer between two gate electrodes of the first transistor T1 on the base substrate. In an exemplary embodiment, the first shield electrode 36 is configured to shield the influence of the data voltage jump on the first transistor T1, and prevent the data voltage jump from affecting the normal operation of the pixel driving circuit, thereby improving the display effect.

In an exemplary embodiment, the at least one circuit unit may further include a second shield electrode 37 connected to the fourth electrode plate 74, and an orthographic projection of the second shield electrode 37 on the base substrate at least partially overlaps with an orthographic projection of a semiconductor layer between two gate electrodes of the second transistor T2 on the base substrate. In an exemplary embodiment, the second shield electrode 37 is configured to shield the influence of the data voltage jump on the second transistor T2, and prevent the data voltage jump from affecting the normal operation of the pixel driving circuit, thereby improving the display effect.

In an exemplary embodiment, the fourth electrode plate 74, the first shield electrode 36 and the second shield electrode 37 may be of an interconnected integral structure.

In an exemplary embodiment, the at least one circuit unit may further include a third shield electrode 38 connected to the fourth electrode plate 74, and an orthographic projection of the third shield electrode 38 on the base substrate at least partially overlaps with an orthographic projection of a semiconductor layer between two gate electrodes of the fourth transistor T4 on the base substrate. In an exemplary embodiment, the third shield electrode 38 is configured to shield the influence of the data voltage jump on the fourth transistor T4, and prevent the data voltage jump from affecting the normal operation of the pixel driving circuit, thereby improving the display effect.

In an exemplary embodiment, the at least one circuit unit may further include a fourth shield electrode 39 connected to the fourth electrode plate 74, and an orthographic projection of the fourth shield electrode 39 on the base substrate at least partially overlaps with an orthographic projection of a semiconductor layer between two gate electrodes of the ninth transistor T9 on the base substrate. In an exemplary embodiment, the fourth shield electrode 39 is configured to shield the influence of the data voltage jump on the ninth transistor T9, and prevent the data voltage jump from affecting the normal operation of the pixel driving circuit, thereby improving the display effect.

Exemplary description is made below through a preparation process for a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed by a patterning process in the entire manufacturing process, the “thin film” may also be called a “layer”. If the “thin film” needs to be processed by a patterning process in the entire manufacturing process, the “thin film” is called a “thin film” before the patterning process is performed and is called a “layer” after the patterning process is performed. At least one “pattern” is contained in the “layer” which has been processed by a patterning process. “A and B are provided in a same layer” in the present disclosure means that A and B are formed simultaneously through a same patterning process, and a “thickness” of a film layer is a dimension of the film in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In an exemplary embodiment, taking one circuit unit in the nth unit row as an example, the preparation process for the display substrate of the present embodiment may include the following operations.

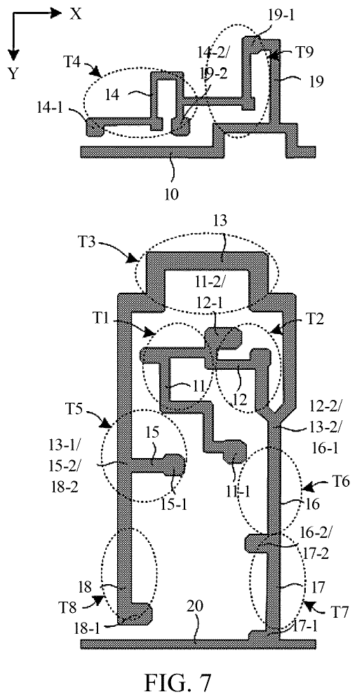

(11) Forming a semiconductor layer. In an exemplary embodiment, forming the pattern of the semiconductor layer may include: sequentially depositing a first insulating thin film and a semiconductor thin film on a base substrate, and patterning the semiconductor thin film by a patterning process to form a first insulating layer covering the base substrate and a semiconductor layer provided on the first insulating layer, as shown in FIG. 7.

In an exemplary embodiment, the semiconductor layer of each circuit unit in the display substrate may at least include a first active layer 11 of the first transistor T1, a second active layer 12 of the second transistor T2, a third active layer 13 of the third transistor T3, a fourth active layer 14 of the fourth transistor T4, a fifth active layer 15 of the fifth transistor T5, a sixth active layer 16 of the sixth transistor T6, a seventh active layer 17 of the seventh transistor T7, an eighth active layer 18 of the eighth transistor T8 and a ninth active layer 19 of the ninth transistor T9. The first active layer 11 to the third active layer 13 and the fifth active layer 15 to the eighth active layer 18 may be of an interconnected integral structure, and the fourth active layer 14 and the ninth active layer 19 may be of an interconnected integral structure.

In an exemplary embodiment, the fourth active layer 14 and the ninth active layer 19 of the nth unit row may be located on a side of the third active layer 13 close to the n−1th unit row, that is, the fourth active layer 14 and the ninth active layer 19 may be located on a side of the third active layer 13 of the present circuit unit in a direction opposite to the second direction Y. The first active layer 11, the second active layer 12, and the fifth active layer 15 to the eighth active layer 18 of the nth unit row may be located on a side of the third active layer 13 close to the n+1th unit row, that is, the first active layer 11, the second active layer 12, and the fifth active layer 15 to the eighth active layer 18 may be located on a side of the third active layer 13 of the present circuit unit in the second direction Y.

In an exemplary embodiments, the first active layer 11 may be located on a side of the third active layer 13 of the present circuit unit in the second direction Y, the fifth active layer 15 may be located on a side of the first active layer 11 of the present circuit unit in the second direction Y, and the eighth active layer 18 may be located on a side of the fifth active layer 15 of the present circuit unit in the second direction Y. The second active layer 12 may be located on a side of the third active layer 13 of the present circuit unit in the second direction Y, the sixth active layer 16 may be located on a side of the second active layer 12 of the present circuit unit in the second direction Y, and the seventh active layer 17 may be located on a side of the sixth active layer 16 of the present circuit unit in the second direction Y.

In an exemplary embodiment, the first active layer 11, the fourth active layer 14, the fifth active layer 15, and the eighth active layer 18 may be located on a side of the present circuit unit in the first direction X (e.g. a side in a direction opposite to the first direction X), and the second active layer 12, the sixth active layer 16, the seventh active layer 17, and the ninth active layer 19 may be located on the other side of the present circuit unit in the first direction X (e.g. a side in the first direction X).

In an exemplary embodiment, the first active layer 11, the second active layer 12, the fourth active layer 14, and the ninth active layer 19 may have an “L” shape, the third active layer 13 may have a “C” shape, and the fifth active layer 15, the sixth active layer 16, the seventh active layer 17, and the eighth active layer 18 may have an “I” shape.

In an exemplary embodiment, the fourth active layer 14 and the ninth active layer 19 may have an “L” shape so that nodes between two gate electrodes of the fourth transistor T4 and the ninth transistor T9 are closer to the VDD signal.

In an exemplary embodiment, an active layer of each transistor may include a first region, a second region, and a channel region located between the first region and the second region. In an exemplary embodiment, a second region 11-2 of the first active layer and a first region 12-1 of the second active layer may be connected to each other, and the second region 11-2 of the first active layer may serve as the first region 12-1 of the second active layer. A first region 13-1 of the third active layer, a second region 15-2 of the fifth active layer, and a second region 18-2 of the eighth active layer may be connected to each other, and the first region 13-1 of the third active layer may serve as the second region 15-2 of the fifth active layer and the second region 18-2 of the eighth active layer simultaneously, forming a second node N2 of the pixel driving circuit. A second region 12-2 of the second active layer, a second region 13-2 of the third active layer and a first region 16-1 of the sixth active layer may be connected to each other, and the second region 13-2 of the third active layer may serve as the second region 12-2 of the second active layer and the first region 16-1 of the sixth active layer simultaneously, forming a third node N3 of the pixel driving circuit. A second region 14-2 of the fourth active layer and a second region 19-2 of the ninth active layer may be connected to each other, and the second region 14-2 of the fourth active layer may serve as the second region 19-2 of the ninth active layer. A second region 16-2 of the sixth active layer and a second region 17-2 of the seventh active layer may be connected to each other, and the second region 16-2 of the sixth active layer may serve as the second region 17-2 of the seventh active layer, forming a fourth node N4 of the pixel driving circuit. A first region 11-1 of the first active layer, a first region 14-1 of the fourth active layer, a first region 15-1 of the fifth active layer, a first region 17-1 of the seventh active layer, a first region 18-1 of the eighth active layer, and a first region 19-1 of the ninth active layer may be provided separately, the first region 14-1 of the fourth active layer may be located on a side of a channel region of the fourth active layer close to the third active layer 13, and the first region 19-1 of the ninth active layer may be located on a side of a channel region of the ninth active layer away from the third active layer 13.

In an exemplary embodiment, the display substrate may further include a first active connection line 10 and a second active connection line 20. The first active connection line 10 may be located on a side of the ninth active layer 19 in the second direction Y, and connected to a first region 19-1 of a ninth active layer of each circuit unit. The second active connection line 20 may be located on a side of the seventh active layer 17 in the second direction Y, and connected to a first region 17-1 of a seventh active layer of each circuit unit.

In an exemplary embodiment, the first active connection line 10 may have a bend line shape in which a main body portion extends in the first direction X, and the first active connection line 10 and ninth active layers of a plurality of circuit units may be of an interconnected integral structure. Since the first region of the ninth active layer is connected to a first reference signal line formed subsequently, the first active connection line 10 may be reused as the first reference signal line extending in the first direction X, which may not only ensure that first regions of a plurality of ninth active layers in a unit row are at a same potential, but also reduce a voltage drop of a first reference signal, which is beneficial to improving the uniformity of a panel, avoiding display defect of the display substrate, and ensuring the display effect of the display substrate.

In an exemplary embodiment, the second active connection line 20 may have a straight line shape in which the main body portion extends in the first direction X, and the second active connection line 20 and seventh active layers of a plurality of circuit units may be of an interconnected integral structure. Since the first region of the seventh active layer is connected to a second initial signal line formed subsequently, the second active connection line 20 may be reused as the second initial signal line extending in the first direction X, which may not only ensure that first regions of a plurality of seventh active layers in a unit row are at a same potential, but also reduce a voltage drop of a second initial signal, which is beneficial to improving the uniformity of a panel, avoiding display defect of the display substrate, and ensuring the display effect of the display substrate.

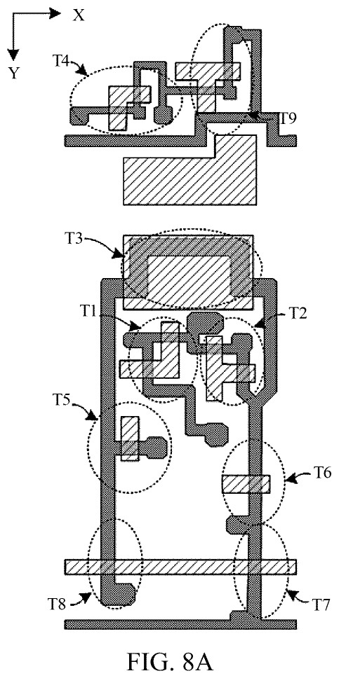

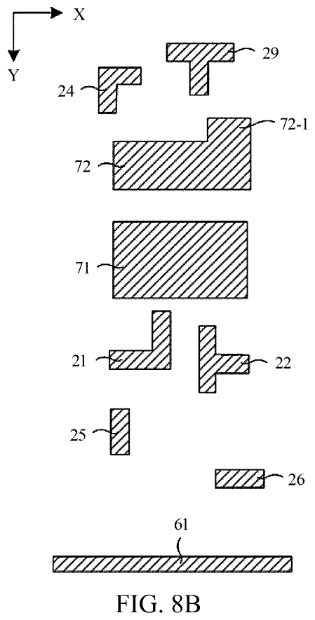

(12) Forming a pattern of a first conductive layer. In an exemplary embodiment, forming the pattern of the first conductive layer may include: sequentially depositing a second insulating thin film and a first conductive thin film on the base substrate on which the aforementioned pattern is formed, and patterning the first conductive thin film by a patterning process to form a second insulating layer covering the pattern of the semiconductor layer and a pattern of a first conductive layer provided on the second insulating layer, as shown in FIG. 8A and FIG. 8B, FIG. 8B being a schematic diagram of the first conductive layer in FIG. 8A. In an exemplary embodiment, the first conductive layer may be referred to as a first gate metal (GATE1) layer.

In an exemplary embodiment, a pattern of a first conductive layer of each circuit unit in the display substrate at least includes a first gate electrode 21, a second gate electrode 22, a fourth gate electrode 24, a fifth gate electrode 25, a sixth gate electrode 26, a ninth gate electrode 29, a first scan signal line 61, a first electrode plate 71 of a first storage capacitor, and a second electrode plate 72 of a second storage capacitor.

In an exemplary embodiment, the first gate electrode 21 may have an “L” shape, which may be located on a side of the first electrode plate 71 in the second direction Y, and a region where the first gate electrode 21 overlaps with the first active layer may serve as a gate electrode of a first transistor T1 with a double-gate structure.

In an exemplary embodiment, the second gate electrode 22 may have a “T” shape, which may be located on a side of the first electrode plate 71 in the second direction Y, and a region where the second gate electrode 22 overlaps with the second active layer may serve as a gate electrode of a second transistor T2 with a double-gate structure.

In an exemplary embodiment, the fourth gate electrode 24 may have an “L” shape, which may be located on a side of the second electrode plate 72 in a direction opposite to the second direction Y, and a region where the fourth gate electrode 24 overlaps with the fourth active layer may serve as a gate electrode of a fourth transistor T4 with a double-gate structure.

In an exemplary embodiment, the fifth gate electrode 25 may have a strip shape extending in the second direction Y, which may be located on a side of the first gate electrode 21 in the second direction Y, and a region where the fifth gate electrode 25 overlaps with the fifth active layer may serve as a gate electrode of a fifth transistor T5.

In an exemplary embodiment, the sixth gate electrode 26 may have a strip shape extending in the first direction X, which may be located on a side of the second gate electrode 22 in the second direction Y, and a region where the sixth gate electrode 26 overlaps with the sixth active layer may serve as a gate electrode of a sixth transistor T6.

In an exemplary embodiment, the ninth gate electrode 29 may have a “T” shape, which may be located on a side of the second electrode plate 72 in a direction opposite to the second direction Y, and a region where the ninth gate electrode 29 overlaps with the ninth active layer may serve as a gate electrode of a ninth transistor T9 with a double-gate structure.

In an exemplary embodiment, the first scan signal line 61 may have a line shape in which the main body portion extends in the first direction X, which may be located on a side of the fifth gate electrode 25 and the sixth gate electrode 26 in the second direction Y, a region where the first scan signal line 61 overlaps with the seventh active layer may serve as a gate electrode of the seventh transistor T7, and a region where the first scan signal line 61 overlaps with the eighth active layer may serve as a gate electrode of the eighth transistor T8.

In an exemplary embodiment, the first electrode plate 71 of the first storage capacitor may have a rectangular shape, an orthographic projection of the first electrode plate 71 on the base substrate at least partially overlaps with an orthographic projection of a third active layer of a third transistor T3 on the base substrate, and the first electrode plate 71 may simultaneously serve as a lower electrode plate of the first storage capacitor and a gate electrode of the third transistor T3.

In an exemplary embodiment, a main body shape of the second electrode plate 72 of the second storage capacitor may be a rectangular shape, which may be located on a side of the first electrode plate 71 in a direction opposite to the second direction Y, and on a side of the fourth gate electrode 24 and the ninth gate electrode 29 in the second direction Y. That is, in the second direction Y, the second electrode plate 72 is located between the first electrode plate 71 and the fourth gate electrode 24 (the ninth gate electrode 29). An orthographic projection of the second electrode plate 72 on the base substrate does not overlap with an orthographic projection of the semiconductor layer on the base substrate. In an exemplary embodiment, the second electrode plate 72 may serve as a lower electrode plate of the second storage capacitor.

In an exemplary embodiment, a region where the first active connection line 10 is connected to the first region of the ninth active layer is bent towards the ninth active layer, so that a recess is formed on a side of the first active connection line 10 away from the ninth active layer. A protrusion 72-1 is provided on a side of the second electrode plate 72 close to the first active connection line 10. The protrusion 72-1 may have a rectangular shape, a first end of the protrusion 72-1 is connected to the second electrode plate 72, and a second end of the protrusion 72-1 extends into the recess of the first active connection line 10.

In an exemplary embodiment, the second electrode plate 72 and the protrusion 72-1 may be of an interconnected integral structure. In the present disclosure, by providing the recess of the first active connection line 10 and the protrusion 72-1 of the second electrode plate 72, an area of the second electrode plate 72 may be effectively increased, and a capacitance of the second storage capacitor may be effectively increased.

In an exemplary embodiment, after the pattern of the first conductive layer is formed, a conductive processing may be performed on the semiconductor layer by using the first conductive layer as a shield, a region of the semiconductor layer shielded by the first conductive layer forms a channel region of the first transistor T1 to the ninth transistor T9, and a region of the semiconductor layer not shielded by the first conductive layer is made to be conductive, that is, first regions and second regions of the first active layer to the ninth active layer are all made to be conductive.

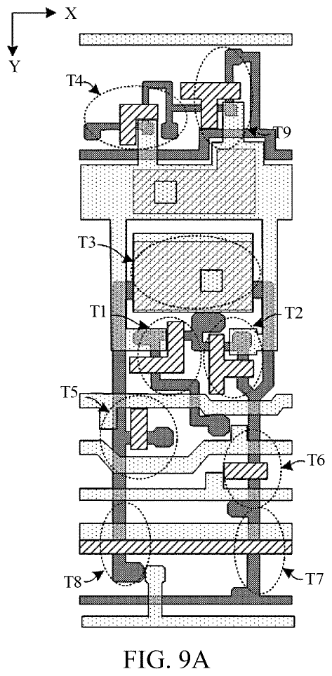

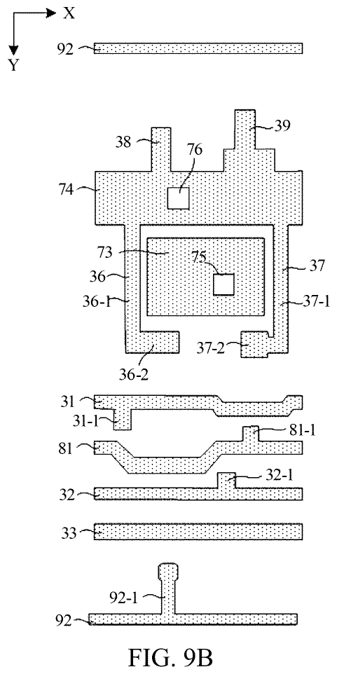

(13) Forming a pattern of a second conductive layer. In an exemplary embodiment, forming the pattern of the second conductive layer may include: sequentially depositing a third insulating thin film and a second conductive thin film on the base substrate on which the aforementioned patterns are formed, and patterning the second conductive thin film by a patterning process to form a third insulating layer covering the first conductive layer and a pattern of the second conductive layer provided on the third insulating layer, as shown in FIG. 9A and FIG. 9B, FIG. 9B being a schematic diagram of the second conductive layer in FIG. 9A. In an exemplary embodiment, the second conductive layer may be referred to as a second gate metal (GATE2) layer.

In an exemplary embodiment, a pattern of a second conductive layer of each circuit unit in the display substrate at least includes a first light emitting signal line 31, a second light emitting signal line 32, a repair line 33, a third electrode plate 73 of a first storage capacitor, a fourth electrode plate 74 of a second storage capacitor, a first initial signal line 81, and a second reference signal line 92.

In an exemplary embodiment, the first light emitting signal line 31, the second light emitting signal line 32, the repair line 33, the first initial signal line 81, and the second reference signal line 92 may each have a line shape in which a main body portion extends in the first direction X. The first light emitting signal line 31, the second light emitting signal line 32, the repair line 33, and the first initial signal line 81 may be located between the first gate electrode 21 and the first scan signal line 61, and the second reference signal line 92 may be located on a side of the fourth gate electrode 24 in a direction opposite to the second direction Y.

In an exemplary embodiment, the first light emitting signal line 31 may be located on a side of the first gate electrode 21 of the present circuit unit in the second direction Y, the first initial signal line 81 may be located on a side of the first light emitting signal line 31 of the present circuit unit in the second direction Y, the second light emitting signal line 32 may be located on a side of the first initial signal line 81 of the present circuit unit in the second direction Y, and the repair line 33 may be located on a side of the second light emitting signal line 32 of the present circuit unit in the second direction Y. That is, the second light emitting signal line 32 and the first initial signal line 81 may be located between the first light emitting signal line 31 and the repair line 33.

In an exemplary embodiment, a first light emitting connection block 31-1 is provided on a side of the first light emitting signal line 31 close to the first initial signal line 81, the first light emitting connection block 31-1 may be provided in each circuit unit, a first end of the first light emitting connection block 31-1 is connected to the first light emitting signal line 31, a second end of the first light emitting connection block 31-1 extends in a direction towards the first initial signal line 81, and the first light emitting connection block 31-1 is configured to be connected to the fifth gate electrode 25 through a seventh connection electrode formed subsequently. In an exemplary embodiment, the first light emitting signal line 31 and a plurality of first light emitting connection blocks 31-1 may be of an interconnected integral structure.

In an exemplary embodiment, a first initial connection block 81-1 is provided on a side of the first initial signal line 81 close to the first light emitting signal line 31. The first initial connection block 81-1 may be provided in each circuit unit, a first end of the first initial connection block 81-1 is connected to the first initial signal line 81, a second end of the first initial connection block 81-1 extends in a direction towards the first light emitting signal line 31, and the first initial connection block 81-1 is configured to be connected to the first region of the first active layer through a ninth connection electrode formed subsequently. In an exemplary embodiment, the first initial signal line 81 and a plurality of first initial connection blocks 81-1 may be of an interconnected integral structure.

In an exemplary embodiment, a second light emitting connection block 32-1 is provided on a side of the second light emitting signal line 32 close to the first initial signal line 81. The second light emitting connection block 32-1 may be provided in each circuit unit, a first end of the second light emitting connection block 32-1 is connected to the second light emitting signal line 32, a second end of the second light emitting connection block 32-1 extends in a direction towards the first initial signal line 81, and the second light emitting connection block 32-1 is configured to be connected to the sixth gate electrode 26 through an eighth connection electrode formed subsequently. In an exemplary embodiment, the second light emitting signal line 32 and a plurality of second light emitting connection blocks 32 may be of an interconnected integral structure.

In an exemplary embodiment, an orthographic projection of the second reference signal line 92 on the base substrate does not overlap with an orthographic projection of the fourth active layer of the fourth transistor T4 on the base substrate, and an orthographic projection of the second reference signal line 92 does not overlap with an orthographic projection of the ninth active layer of the ninth transistor T9 on the base substrate, thereby greatly reducing the capacitance between the scan signal and the signal of the second reference signal line 92 and improving the driving load of the gate driving circuit.

In an exemplary embodiment, a second reference connection block 92-1 is provided on a side of the second reference signal line 92 in the nth unit row away from the second electrode plate 72 in the nth unit row. The second reference connection block 92-1 may be provided in each circuit unit, a first end of the second reference connection block 92-1 is connected to the second reference signal line 92, and a second end of the second reference connection block 92-1 extends in a direction away from the second electrode plate 72, that is, in a direction towards an n−1th unit row. In an exemplary embodiment, the second reference connection block 92-1 of the second reference signal line 92 in the n-th unit row is configured to be connected to the first region of the eighth active layer in the n−1th unit row through a sixth connection electrode formed subsequently, so as to provide a second reference signal to a first electrode of the eighth transistor T8 in the n−1th unit row. In an exemplary embodiment, the second reference signal line 92 and a plurality of second reference connection blocks 92-1 may be of an interconnected integral structure.

In an exemplary implementation, a contour shape of the third electrode plate 73 of the first storage capacitor may be a shape of rectangle, corners of the rectangle may be chamfered. The third electrode plate 73 of the first storage capacitor may be located between the first light emitting signal line 31 and the second reference signal line 92 in the present circuit unit, an orthographic projection of the third electrode plate 73 on the base substrate at least partially overlaps with an orthographic projection of the first electrode plate 71 on the base substrate, the third electrode plate 73 may serve as an upper electrode plate of the first storage capacitor, and the first electrode plate 71 and the third electrode plate 33 form the first storage capacitor of the pixel driving circuit.

In an exemplary embodiment, a contour shape of the fourth electrode plate 74 of the second storage capacitor may be similar to that of the second electrode plate 72, the fourth electrode plate 74 of the second storage capacitor may be located between the second reference signal line 92 and the third electrode plate 73 in the present circuit unit, an orthographic projection of the fourth electrode plate 74 on the base substrate at least partially overlaps with an orthographic projection of the second electrode plate 72 on the base substrate, the fourth electrode plate 74 may serve as an upper electrode plate of the second storage capacitor, and the second electrode plate 72 and the fourth electrode plate 74 form the second storage capacitor C2 of the pixel driving circuit.

In an exemplary embodiment, a side of the fourth electrode plate 74 close to the first light emitting signal line 31 is provided with a first shield electrode 36, which is located on a side of the fourth electrode plate 74 in the second direction Y. The first shield electrode 36 may have an “L” shape, and may be provided in each circuit unit. The first shield electrode 36 having an “L” shape may include a first extension segment 36-1 and a first shield segment 36-2. The first extension segment 36-1 may have a strip shape extending in the second direction Y. A first end of the first extension segment 36-1 is connected to the fourth electrode plate 74, and a second end of the first extension segment 36-1 extends toward the first light emitting signal line 31 and is connected to a first end of the first shield segment 36-2. The first shield segment 36-2 may have a strip shape extending in the first direction X. A first end of the first shield segment 36-2 is connected to the second end of the first extension segment 36-1, a second end of the first shield segment 36-2 extends in the first direction X, and an orthographic projection of the first shield segment 36-2 on the base substrate at least partially overlaps with an orthographic projection of the first active layer between two gate electrodes of the first transistor T1 on the base substrate. In an exemplary embodiment, the first shield electrode 36 is configured to shield the influence of the data voltage jump on the first transistor T1, and prevent the data voltage jump from affecting the normal operation of the pixel driving circuit, thereby improving the display effect.

In an exemplary embodiment, the fourth electrode plate 74 and the first shield electrode 36 may be of an interconnected integral structure.

In an exemplary embodiment, a side of the fourth electrode plate 74 close to the first light emitting signal line 31 is provided with a second shield electrode 37, which is located on a side of the fourth electrode plate 74 in the second direction Y. The second shield electrode 37 may have an “L” shape, and may be provided in each circuit unit. The second shield electrode 37 having an “L” shape may include a second extension segment 37-1 and a second shield segment 37-2. The second extension segment 37-1 may have a strip shape extending in the second direction Y. A first end of the second extension segment 37-1 is connected to the fourth electrode plate 74, and a second end of the second extension segment 37-1 extends toward the first light emitting signal line 31 and is connected to the second shield segment 37-2. The second shield segment 37-2 may have a strip shape extending in a direction opposite to the first direction X, a first end of the second shield segment 37-2 is connected to a second end of the second extension segment 37-1, a second end of the second shield segment 37-2 extends in a direction opposite to the first direction X, and an orthographic projection of the second shield segment 37-2 on the base substrate at least partially overlaps with an orthographic projection of the second active layer between two gate electrodes of the second transistor T2 on the base substrate. In an exemplary embodiment, the second shield electrode 37 is configured to shield the influence of the data voltage jump on the second transistor T2, and prevent the data voltage jump from affecting the normal operation of the pixel driving circuit, thereby improving the display effect.

In an exemplary embodiment, the fourth electrode plate 74 and the second shield electrode 37 may be of an interconnected integral structure.

In an exemplary embodiment, a side of the fourth electrode plate 74 away from the first light emitting signal line 31 is provided with a third shield electrode 38, which is located on a side of the fourth electrode plate 74 in a direction opposite to the second direction Y. The third shield electrode 38 may have a strip shape extending in the second direction Y, a first end of the third shield electrode 38 is connected to the fourth electrode plate 74, a second end of the third shield electrode 38 extends in a direction towards the second reference signal line 92, and the third shield electrode 38 may be provided in each circuit unit. An orthographic projection of the third shield electrode 38 on the base substrate at least partially overlaps with an orthographic projection of the fourth active layer between two gate electrodes of the fourth transistor T4 on the base substrate. In an exemplary embodiment, the third shield electrode 38 is configured to shield the influence of the data voltage jump on the fourth transistor T4, and prevent the data voltage jump from affecting the normal operation of the pixel driving circuit, thereby improving the display effect.

In an exemplary embodiment, the fourth electrode plate 74 and the third shield electrode 38 may be of an interconnected integral structure.

In an exemplary embodiment, a side of the fourth electrode plate 74 away from the first light emitting signal line 31 is provided with a fourth shield electrode 39, which is located on a side of the fourth electrode plate 74 in the second direction Y. The fourth shield electrode 39 may have a strip shape extending in the second direction Y, a first end of the fourth shield electrode 39 is connected to the fourth electrode plate 74, a second end of the fourth shield electrode 39 extends in a direction towards the second reference signal line 92, and the fourth shield electrode 39 may be provided in each circuit unit. An orthographic projection of the fourth shield electrode 39 on the base substrate at least partially overlaps with an orthographic projection of the ninth active layer between two gate electrodes of the ninth transistor T9 on the base substrate. In an exemplary embodiment, the fourth shield electrode 39 is configured to shield the influence of the data voltage jump on the ninth transistor T9, and prevent the data voltage jump from affecting the normal operation of the pixel driving circuit, thereby improving the display effect.

In an exemplary embodiment, the fourth electrode plate 74 and the fourth shield electrode 39 may be of an interconnected integral structure.

In an exemplary implementation, the third electrode plate 73 of each circuit unit is provided with a first opening 75, which may be located in a middle of the third electrode plate 73. The first opening 75 may have a rectangular shape such that the third electrode plate 73 forms an annular structure. The first opening 75 exposes the third insulating layer covering the first electrode plate 71, and an orthographic projection of the first electrode plate 71 on the base substrate includes an orthographic projection of the first opening 75 on the base substrate. In an exemplary implementation, the first opening 75 is configured to accommodate a tenth via formed subsequently, and the tenth via is located within the first opening 75 and exposes the first electrode plate 71, so that a first connection electrode formed subsequently is connected to the first electrode plate 71.

In an exemplary embodiment, the fourth electrode plate 74 of each circuit unit is provided with a second opening 76, which may be located in a middle of the fourth electrode plate 74. The second opening 76 may have a rectangular shape such that the fourth electrode plate 74 forms an annular structure. The second opening 76 exposes the third insulating layer covering the first electrode plate 72, and an orthographic projection of the second electrode plate 72 on the base substrate includes an orthographic projection of the second opening 76 on the base substrate. In an exemplary embodiment, the second opening 76 is configured to accommodate an eleventh via formed subsequently, and the eleventh via is located within the second opening 76 and exposes the second electrode plate 72, so that a second connection electrode formed subsequently is connected to the second electrode plate 72.

In an exemplary implementation, the repair line 33 serves as a pre-set repair signal line, so that when a bright spot defect occurs in the display substrate, a signal is inputted to an anode of a sub-pixel where the bright spot defect occurs through the repair line 33 to repair the defective bright spot to a dark spot.

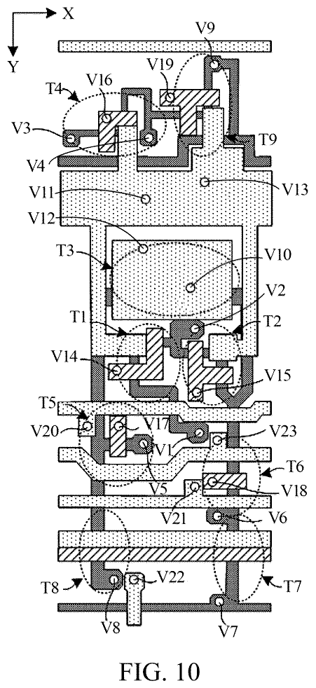

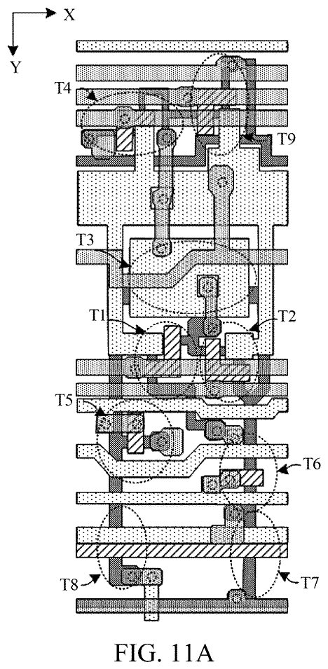

(14) Forming a pattern of a fourth insulating layer. In an exemplary embodiment, forming the pattern of the fourth insulating layer may include: depositing a fourth insulating thin film on the base substrate on which the aforementioned patterns are formed, and patterning the fourth insulating thin film by a patterning process, to form a fourth insulating layer covering the second conductive layer, a plurality of vias are provided in each circuit unit, as shown in FIG. 10.

In an exemplary embodiment, the plurality of vias in each circuit unit in the display substrate at least include a first via V1, a second via V2, a third via V3, a fourth via V4, a fifth via V5, a sixth via V6, a seventh via V7, an eighth via V8, a ninth via V9, a tenth via V10, an eleventh via V11, a twelfth via V12, a thirteenth via V13, a fourteenth via V14, a fifteenth via V15, a sixteenth via V16, a seventeenth via V17, an eighteenth via V18, a nineteenth via V19, a twentieth via V20, a twenty-first via V21, a twenty-second via V22, and a twenty-third via V23.

In an exemplary embodiment, an orthographic projection of the first via V1 on the base substrate is within a range of an orthographic projection of the first region of the first active layer on the base substrate. The fourth insulating layer, the third insulating layer and the second insulating layer within the first via V1 are etched away to expose a surface of the first region of the first active layer, and the first via V1 is configured such that a ninth connection electrode formed subsequently is connected to the first region of the first active layer through the first via.

In an exemplary embodiment, an orthographic projection of the second via V2 on the base substrate is within a range of an orthographic projection of the second region of the first active layer (i.e., the first region of the second active layer) on the base substrate. The fourth insulating layer, the third insulating layer and the second insulating layer within the second via V2 are etched away to expose a surface of the second region of the first active layer (i.e., the first region of the second active layer), and the second via V2 is configured such that a first connection electrode formed subsequently is connected to the second region of the first active layer (i.e., the first region of the second active layer) through the second via.

In an exemplary embodiment, an orthographic projection of the third via V3 on the base substrate is within a range of an orthographic projection of the first region of the fourth active layer on the base substrate. The fourth insulating layer, the third insulating layer and the second insulating layer within the third via V3 are etched away to expose a surface of the first region of the fourth active layer, and the third via V3 is configured such that a third connection electrode formed subsequently is connected to the first region of the fourth active layer through the third via.

In an exemplary embodiment, an orthographic projection of the fourth via V4 on the base substrate is within a range of an orthographic projection of the second region of the fourth active layer (i.e., the second region of the ninth active layer) on the base substrate. The fourth insulating layer, the third insulating layer and the second insulating layer within the fourth via V4 are etched away to expose a surface of the second region of the fourth active layer (i.e., the second region of the ninth active layer), and the fourth via V4 is configured such that a second connection electrode formed subsequently is connected to the second region of the fourth active layer (i.e., the second region of the ninth active layer) through the fourth via.

In an exemplary embodiment, an orthographic projection of the fifth Via V5 on the base substrate is within a range of an orthographic projection of the first region of the fifth active layer on the base substrate. The fourth insulating layer, the third insulating layer and the second insulating layer within the fifth Via V5 are etched away to expose a surface of the first region of the fifth active layer, and the fifth Via V5 is configured such that a fourth connection electrode formed subsequently is connected to the first region of the fifth active layer through the fifth via.

In an exemplary embodiment, an orthographic projection of the sixth via V6 on the base substrate is within a range of an orthographic projection of the second region of the sixth active layer (i.e., the second region of the seventh active layer) on the base substrate. The fourth insulating layer, the third insulating layer and the second insulating layer within the sixth via V6 are etched away to expose a surface of the second region of the sixth active layer (i.e., the second region of the seventh active layer), and the sixth via V6 is configured such that a fifth connection electrode formed subsequently is connected to the second region of the sixth active layer (i.e., the second region of the seventh active layer) through the sixth via.

In an exemplary embodiment, an orthographic projection of the seventh via V7 on the base substrate is within a range of an orthographic projection of the first region of the seventh active layer on the base substrate. The fourth insulating layer, the third insulating layer and the second insulating layer within the seventh via V7 are etched away to expose a surface of the first region of the seventh active layer, and the seventh via V7 is configured such that a second initial signal line formed subsequently is connected to the first region of the seventh active layer through the seventh via.

In an exemplary embodiment, an orthographic projection of the eighth via V8 on the base substrate is within a range of an orthographic projection of the first region of the eighth active layer on the base substrate. The fourth insulating layer, the third insulating layer and the second insulating layer within the eighth via V8 are etched away to expose a surface of the first region of the eighth active layer, and the eighth via V8 is configured such that a sixth connection electrode formed subsequently is connected to the first region of the eighth active layer through the eighth via.

In an exemplary embodiment, an orthographic projection of the ninth via V9 on the base substrate is within a range of an orthographic projection of the first region of the ninth active layer on the base substrate. The fourth insulating layer, the third insulating layer and the second insulating layer within the ninth via V9 are etched away to expose a surface of the first region of the ninth active layer, and the ninth via V9 is configured such that a first reference signal line formed subsequently is connected to the first region of the ninth active layer through the ninth via.

In an exemplary embodiment, an orthographic projection of the tenth via V10 on the base substrate is located within a range of an orthographic projection of the first opening 75 of the third electrode plate 73 on the base substrate. The fourth insulating layer and the third insulating layer within the tenth via V10 are etched away to expose a surface of the first electrode plate 71, and the tenth via V10 is configured such that a first connection electrode formed subsequently is connected to the first electrode plate 71 through the tenth via.

In an exemplary embodiment, an orthographic projection of the eleventh via V11 on the base substrate is within a range of an orthographic projection of the second opening 76 of the fourth electrode plate 74 on the base substrate. The fourth insulating layer and the third insulating layer within the eleventh via V11 are etched away to expose a surface of the second electrode plate 72, and the eleventh via V11 is configured such that a second connection electrode formed subsequently is connected to the second electrode plate 72 through the eleventh via.

In an exemplary embodiment, an orthographic projection of the twelfth via V12 on the base substrate is within a range of an orthographic projection of the third electrode plate 73 on the base substrate. The fourth insulating layer within the twelfth via V12 is etched away to expose a surface of the third electrode plate 73, and the twelfth via V12 is configured such that a second connection electrode formed subsequently is connected to the third electrode plate 73 through the twelfth via.

In an exemplary embodiment, an orthographic projection of the thirteenth via V13 on the base substrate is within a range of an orthographic projection of the fourth electrode plate 74 on the base substrate. The fourth insulating layer within the thirteenth via V13 is etched away to expose a surface of the fourth electrode plate 74, and the thirteenth via V13 is configured such that a first power supply connection line formed subsequently is connected to the fourth electrode plate 74 through the thirteenth via.

In an exemplary embodiment, an orthographic projection of the fourteenth via V14 on the base substrate is within a range of an orthographic projection of the first gate electrode 21 on the base substrate. The fourth insulating layer and the third insulating layer within the fourteenth via V14 are etched away to expose a surface of the first gate electrode 21, and the fourteenth via V14 is configured such that a fourth scan signal line formed subsequently is connected to the first gate electrode 21 through the fourteenth via.

In an exemplary embodiment, an orthographic projection of the fifteenth via V15 on the base substrate is within a range of an orthographic projection of the second gate electrode 22 on the base substrate. The fourth insulating layer and the third insulating layer within the fifteenth via V15 are etched away to expose a surface of the second gate electrode 22, and the fifteenth via V15 is configured such that a fifth scan signal line formed subsequently is connected to the second gate electrode 22 through the fifteenth via.

In an exemplary embodiment, an orthographic projection of the sixteenth via V16 on the base substrate is within a range of an orthographic projection of the fourth gate electrode 24 on the base substrate. The fourth insulating layer and the third insulating layer within the sixteenth via V16 are etched away to expose a surface of the fourth gate electrode 24, and the sixteenth via V16 is configured such that a third scan signal line formed subsequently is connected to the fourth gate electrode 24 through the sixteenth via.

In an exemplary embodiment, an orthographic projection of the seventeenth via V17 on the base substrate is within a range of an orthographic projection of the fifth gate electrode 25 on the base substrate. The fourth insulating layer and the third insulating layer within the seventeenth via V17 are etched away to expose a surface of the fifth gate electrode 25, and the seventeenth via V17 is configured such that a seventh connection electrode formed subsequently is connected to the fifth gate electrode 25 through the seventeenth via.

In an exemplary embodiment, an orthographic projection of the eighteenth via V18 on the base substrate is within a range of an orthographic projection of the sixth gate electrode 26 on the base substrate. The fourth insulating layer and the third insulating layer within the eighteenth via V18 are etched away to expose a surface of the sixth gate electrode 26, and the eighteenth via V18 is configured such that an eighteenth connection electrode formed subsequently is connected to the sixth gate electrode 26 through the eighteenth via.

In an exemplary embodiment, an orthographic projection of the nineteenth via V19 on the base substrate is within a range of an orthographic projection of the ninth gate electrode 29 on the base substrate. The fourth insulating layer and the third insulating layer within the nineteenth via V19 are etched away to expose a surface of the ninth gate electrode 29, and the nineteenth via V19 is configured such that a second scan signal line formed subsequently is connected to the ninth gate electrode 29 through the nineteenth via.

In an exemplary embodiment, an orthographic projection of the twentieth via V20 on the base substrate is within an orthographic projection of the first light emitting connection block 31-1 of the first light emitting signal line 31 on the base substrate. The fourth insulating layer within the twentieth via V20 is etched away to expose a surface of the first light emitting connection block 31-1, and the twentieth via V20 is configured such that a seventh connection electrode formed subsequently is connected to the first light emitting connection block 31-1 through the twentieth via.

In an exemplary embodiment, an orthographic projection of the twenty-first via V21 on the base substrate is within an orthographic projection of the second light emitting connection block 32-1 of the second light emitting signal line 32 on the base substrate. The fourth insulating layer within the twenty-first via V21 is etched away to expose a surface of the second light emitting connection block 32-1, and the twenty-first via V21 is configured such that an eighth connection electrode formed subsequently is connected to the second light emitting connection block 32-1 through the twenty-first via.

In an exemplary embodiment, an orthographic projection of the twenty-second via V22 on the base substrate is within a range of an orthographic projection of the second reference connection block 92-1 of the second reference signal line 92 on the base substrate. The fourth insulating layer within the twenty-second via V22 is etched away to expose a surface of the second reference connection block 92-1, and the twenty-second via V22 is configured such that the sixth connection electrode formed subsequently is connected to the second reference connection block 92-1 through the twenty-second via.

In an exemplary embodiment, an orthographic projection of the twenty-third via V23 on the base substrate is within an orthographic projection of the first initial connection block 81-1 of the first initial signal line 81 on the base substrate. The fourth insulating layer within the twenty-third via V23 is etched away to expose a surface of the first initial connection block 81-1, and the twenty-third via V23 is configured such that a ninth connection electrode formed subsequently is connected to the first initial connection block 81-1 through the twenty-third via.

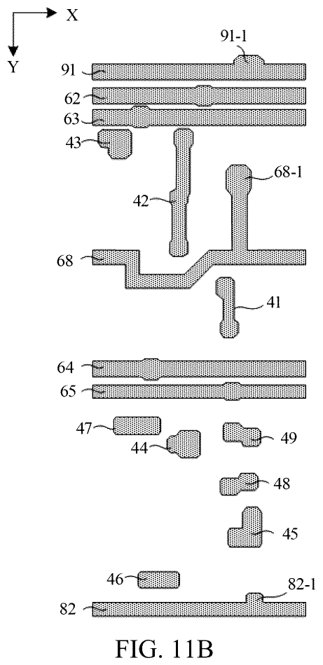

(15) Forming a pattern of a third conductive layer. In an exemplary embodiment, forming the pattern of the third conductive layer may include: depositing a third conductive thin film on the base substrate on which the aforementioned patterns are formed, and patterning the third conductive thin film by a patterning process to form the third conductive layer provided on the fourth insulating layer, as shown in FIG. 11A and FIG. 11B, FIG. 11B being a schematic diagram of the third conductive layer in FIG. 11A. In an exemplary embodiment, the third conductive layer may be referred to as a first source-drain metal (SD1) layer.

In an exemplary embodiment, the pattern of the third conductive layer in each of the plurality of circuit units in the display substrate may include a first connection electrode 41, a second connection electrode 42, a third connection electrode 43, a fourth connection electrode 44, a fifth connection electrode 45, a sixth connection electrode 46, a seventh connection electrode 47, an eighth connection electrode 48, a ninth connection electrode 49, a second scan signal line 62, a third scan signal line 63, a fourth scan signal line 64, a fifth scan signal line 65, a first power supply connection line 68, a second initial signal line 82, and a first reference signal line 91.

In an exemplary embodiment, the second scan signal line 62, the third scan signal line 63, the fourth scan signal line 64, the fifth scan signal line 65, the first power supply connection line 68, the second initial signal line 82, and the first reference signal line 91 may each have a line shape in which the main body portion extends in the first direction X. The second scan signal line 62, the third scan signal line 63, and the first reference signal line 91 may be located on a side of the fourth electrode plate 74 in a direction opposite to the second direction Y, the fourth scan signal line 64, the fifth scan signal line 65, and the second initial signal line 82 may be located on a side of the third electrode plate 73 in the second direction Y, the first power supply connection line 68 may be located on a side of the fourth electrode plate 74 in the second direction Y, and an orthographic projection of the first power supply connection line 68 on the base substrate at least partially overlaps with an orthographic projection of the third electrode plate 73 on the base substrate.

In an exemplary embodiment, the third scan signal line 63 may be located on a side of the fourth electrode plate 74 in a direction opposite to the second direction Y, the second scan signal line 62 may be located on a side of the third scan signal line 63 in a direction opposite to the second direction Y, and the first reference signal line 91 may be located on a side of the second scan signal line 62 in a direction opposite to the second direction Y.

In an exemplary implementation, the fourth scan signal line 64 may be located on a side of the third electrode plate 73 in the second direction Y, the fifth scan signal line 65 may be located on a side of the fourth scan signal line 64 in the second direction Y, and the second initial signal line 82 may be located on a side of the fifth scan signal line 65 in the second direction Y.

In an exemplary embodiment, the first power supply connection line 68 may have a bend line shape in which the main body portion extends in the first direction X, and an orthographic projection of the first power supply connection line 68 on the base substrate does not overlap with an orthographic projection of the fourth electrode plate 74 on the base substrate. The first power supply connection line 68 is configured to be connected to a first power supply line formed subsequently, to form a high-voltage power supply grid structure with a mesh communication structure on the display substrate.

In an exemplary implementation, the second scan signal line 62 is connected to the ninth gate electrode 29 in each circuit unit through the nineteenth via V19, thereby achieving that the second scan signal line 62 is connected to the ninth gate electrode 29 of the ninth transistor T9, and the second scan signal line 62 may control turn-on and turn-off of the ninth transistor T9.

In an exemplary implementation, the fifth scan signal line 65 is connected to the second gate electrode 22 in each circuit unit through the fifteenth via V15, thereby achieving that the fifth scan signal line 65 is connected to the second gate electrode 22 of the second transistor T2, and the fifth scan signal line 65 may control turn-on and turn-off of the second transistor T2.

In an exemplary embodiment, the second scan signal line 62 and the fifth scan signal line 65 may extend to the bezel area and then be connected to a same gate driving circuit so as to output a same scan signal.

In an exemplary embodiment, the third scan signal line 63 is connected to the fourth gate electrode 24 in each circuit unit through the sixteenth via V16, thereby achieving that the third scan signal line 63 is connected to the fourth gate electrode 24 of the fourth transistor T4, and the third scan signal line 63 may control turn-on and turn-off of the fourth transistor T4.

In an exemplary implementation, the fourth scan signal line 64 is connected to the first gate electrode 21 in each circuit unit through the fourteenth via V14, thereby achieving that the fourth scan signal line 64 is connected to the first gate electrode 21 of the first transistor T1, and the fourth scan signal line 64 may control turn-on and turn-off of the first transistor T1.

In an exemplary embodiment, the second initial signal line 82 is connected to the first region of the seventh active layer in each circuit unit through the seventh via V7, thereby achieving that the second initial signal line 82 is connected to the first electrode of the seventh transistor T7, and the second initial signal line 82 may write a second initial signal to the first electrode of the seventh transistor T7.

In an exemplary embodiment, because the second active connection line 20 of the semiconductor layer is directly connected to the first region of the seventh active layer of a plurality of circuit units in a unit row, and the second initial signal line 82 of the third conductive layer is connected to the first regions of the seventh active layers of the plurality of circuit units in the unit row through a via, the second active connection line 20 and the second initial signal line 82 form a signal line with a double-layer structure, which not only ensures that the first regions of the seventh active layers in the unit row have a same potential, but also reduces a resistance of the signal lines, and reduces a voltage drop of the second initial signal, thereby improving the uniformity of the panel, avoiding the display defect of the display substrate, and ensuring the display effect of the display substrate.

In an exemplary embodiment, a side of the second initial signal line 82 close to the fifth scan signal line 65 is provided with a second initial connection block 82-1, a first end of the second initial connection block 82-1 is connected to the second initial signal line 82, and a second end of the second initial connection block 82-1 extends in a direction towards the fifth scan signal line 65 and is connected to the first region of the seventh active layer through the seventh via V7.

In an exemplary embodiment, the first reference signal line 91 is connected to the first region of the ninth active layer in each circuit unit through the ninth via V9, thereby achieving that the first reference signal line 91 is connected to the first electrode of the ninth transistor T9, and the first reference signal line 91 may write a first reference signal to the first electrode of the ninth transistor T9.

In an exemplary implementation, because the first active connection line 10 of the semiconductor layer is directly connected to first regions of ninth active layers of a plurality of circuit units in a unit row, and the first reference signal line 91 of the third conductive layer is connected to the first regions of the ninth active layers of the plurality of circuit units in the unit row through a via, the first active connection line 10 and the first reference signal line 91 form a signal line with a double-layer structure, which not only ensures that the first regions of the plurality of ninth active layers in the unit row have a same potential, but also reduces a resistance of the signal lines, and reduces a voltage drop of the first reference signal, thereby improving the uniformity of the panel, avoiding the display defect of the display substrate, and ensuring the display effect of the display substrate.

In an exemplary embodiment, a side of the first reference signal line 91 away from the second scan signal line 62 is provided with a first reference connection block 91-1, a first end of the first reference connection block 91-1 is connected to the first reference signal line 91, and the second end of the first reference connection block 91-1 extends in a direction away from the second scan signal line 62. The first reference connection block 91-1 is configured to be connected to a reference signal connection line formed subsequently.

In an exemplary embodiment, the first power supply connection line 68 is connected to the fourth electrode plate 74 in each circuit unit through the thirteenth via V13, thereby achieving that the first power supply connection line 68 is connected to the fourth electrode plate 74. Because the first power supply connection line 68 is connected to a first power supply line formed subsequently, the first power supply connection line 68 may write a first power supply signal to the upper electrode plate of the second storage capacitor.

In an exemplary embodiment, a side of the first power supply connection line 68 close to the fourth electrode plate 74 is provided with a first power supply connection block 68-1, a first end of the first power supply connection block 68-1 is connected to the first power supply connection line 68, and a second end of the first power supply connection block 68-1 extends in a direction towards the fourth electrode plate 74. In an exemplary embodiment, the first power supply connection block 68-1 is configured, on the one hand, to be connected to the fourth electrode plate 74 through the thirteenth via V13, and, on the other hand, to be connected to a first power supply line formed subsequently.

In an exemplary embodiment, the first connection electrode 41 may have a strip shape in which the main body portion extends in the second direction Y, and may be provided on a side of the first power supply connection line 64 close to the fourth scan signal line 64. A first end of the first connection electrode 41 is connected to the second region of the first active layer (i.e., the first region of the second active layer) through the second via V2, and a second end of the first connection electrode 41 is connected to the first electrode plate 71 through the tenth via V10.

In an exemplary embodiment, the first connection electrode 41 enables the second electrode of the first transistor T1, the first electrode of the second transistor T2 and the first electrode plate 71 of the first storage capacitor to have a same potential, and the first connection electrode 41 may serve as the first node N1 in the pixel driving circuit.

In an exemplary embodiment, the second connection electrode 42 may have a strip shape in which the main body portion extends in the second direction Y, and may be provided on a side of the first reference signal line 91 close to the first power supply connection line 68. A first end of the second connection electrode 42 is connected to the third electrode plate 73 through the twelfth via V12, a second end of the second connection electrode 42 is connected to the second region of the fourth active layer (i.e., the second region of the ninth active layer) through the fourth via V4, and a middle between the first end and the second end of the second connection electrode 42 is connected to the second electrode plate 72 through the eleventh via V11.

In an exemplary embodiment, the second connection electrode 42 enables the second electrode of the fourth transistor T4, the second electrode of the ninth transistor T9, the third electrode plate 73 of the first storage capacitor and the second electrode plate 72 of the second storage capacitor to have a same potential, and the second connection electrode 42 may serve as the fifth node N5 in the pixel driving circuit.

In an exemplary embodiment, the third connection electrode 43 may have a block shape, and may be located between the first reference signal line 91 and the first power supply connection line 68. The third connection electrode 43 may be connected to the first region of the fourth active layer through the third via V3. In an exemplary embodiment, the third connection electrode 43 may serve as the first electrode of the fourth transistor T4, and is configured to be connected to a data signal line formed subsequently.

In an exemplary embodiment, the fourth connection electrode 44 may have a block shape, and may be located between the fifth scan signal line 65 and the second initial signal line 82. The fourth connection electrode 44 is connected to the first region of the fifth active layer through the fifth via V5. In an exemplary embodiment, the fourth connection electrode 44 may serve as the first electrode of the fifth transistor T5, and is configured to be connected to the first power supply line formed subsequently.

In an exemplary embodiment, the fifth connection electrode 45 may have an “L” shape, and may be located between the fifth scan signal line 65 and the second initial signal line 82. The fifth connection electrode 45 is connected to the second region of the sixth active layer (i.e., the second region of the seventh active layer) through the sixth via V6. In an exemplary embodiment, the fifth connection electrode 45 may serve as the second electrode of the sixth transistor T6 and the second electrode of the seventh transistor T7, and is configured to be connected to an anode connection electrode formed subsequently.

In an exemplary embodiment, the sixth connection electrode 46 may have a strip shape in which the main body portion extends in the first direction X, and may be located between the fifth scan signal line 65 and the second initial signal line 82. A first end of the sixth connection electrode 46 is connected to the first region of the eighth active layer through the eighth via V8, and a second end of the sixth connection electrode 46 is connected to the second reference connection block 92-1 through the twenty-second via V22. In an exemplary embodiment, the sixth connection electrode 46 may serve as the first electrode of the eighth transistor T8. Since the second reference connection block 92-1 is connected to the second reference signal line 92, it is achieved that the second reference signal line 92 is connected to the first electrode of the eighth transistor T8, and the second reference signal line 92 in the nth unit row may write a second reference signal to the first electrode of the eighth transistor T8 in the n−1th unit row.

In an exemplary embodiment, the seventh connection electrode 47 may have a strip shape in which the main body portion extends in the first direction X, and may be located between the fifth scan signal line 65 and the second initial signal line 82. A first end of the seventh connection electrode 47 is connected to the fifth gate electrode 25 through the seventeenth via V17, and a second end of the seventh connection electrode 47 is connected to the first light emitting connection block 31-1 through the twentieth via V20. Because the first light-emitting connecting block 31-1 is connected to the first light-emitting signal line 31, it is achieved that the first light-emitting signal line 31 is connected to the fifth gate electrode 25 of the fifth transistor T5, and the first light-emitting signal line 31 may control turn-on and turn-off of the fifth transistor T5.

In an exemplary embodiment, the eighth connection electrode 48 may have a strip shape in which the main body portion extends in the first direction X, and may be located between the fifth scan signal line 65 and the second initial signal line 82. A first end of the eighth connection electrode 48 is connected to the sixth gate electrode 26 through the eighteenth via V18, and a second end of the eighth connection electrode 48 is connected to the second light emitting connection block 32-1 through the twenty-first via V21. Since the second light-emitting connecting block 32-1 is connected to the second light-emitting signal line 32, it is achieved that the second light-emitting signal line 32 is connected to the sixth gate electrode 26 of the sixth transistor T6, and the second light-emitting signal line 32 may control turn-on and turn-off of the sixth transistor T6.

In an exemplary embodiment, the ninth connection electrode 49 may have a strip shape in which the main body portion extends in the first direction X, and may be located between the fifth scan signal line 65 and the second initial signal line 82. A first end of the ninth connection electrode 49 is connected to the first region of the first active layer through the first via V1, and a second end of the ninth connection electrode 49 is connected to the first initial connection block 81-1 through the twenty-third via V23. Because the first initial connection block 81-1 is connected to the first initial signal line 81, it is achieved that the first initial signal line 81 is connected to the first electrode of the first transistor T1, and the first initial signal line 81 may write a first initial signal to the first electrode of the first transistor T1.

In an exemplary embodiment, because the first electrode plate 71 is connected to the second region of the first active layer (i.e., the first region of the second active layer) through the first connection electrode 41, the first electrode plate 71 has a potential of the first node N1. Because the third electrode plate 73 is connected to the second region of the fourth active layer (i.e., the second region of the ninth active layer) through the second connection electrode 42, the third electrode plate 73 has a potential of the fifth node N5. Thus, the first electrode plate 71 having the potential of the first node N1 and the third electrode plate 73 having the potential of the fifth node N5 form the first storage capacitor of the pixel driving circuit.

In an exemplary embodiment, because the second electrode plate 72 is connected to the second region of the fourth active layer (i.e., the second region of the ninth active layer) through the second connection electrode 42, the second electrode plate 72 has a potential of the fifth node N5. Because the fourth electrode plate 74 is connected to the first power supply connection line 68, which is connected to the first power supply line formed subsequently, the fourth electrode plate 74 has a potential of the first power supply line. Thus, the second electrode plate 72 having the potential of the fifth node N5 and the fourth electrode plate 74 having the potential of the first power supply line form the second storage capacitor of the pixel driving circuit.

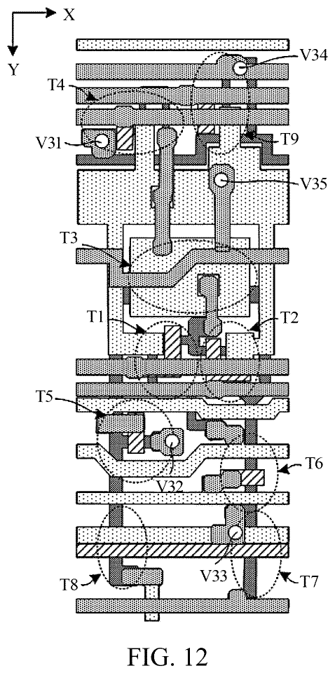

(16) Forming a pattern of a fifth insulating layer. In an exemplary embodiment, forming the pattern of the fifth insulating layer may include: depositing a fifth insulating film on the base substrate on which the aforementioned patterns are formed, and patterning the fifth insulating film by a patterning process to form a fifth insulating layer covering the third conductive layer, a plurality of vias being provided in each circuit unit, as shown in FIG. 12.

In an exemplary embodiment, the plurality of vias in each circuit unit in the display substrate at least includes a thirty-first via V31, a thirty-second via V32, a thirty-third via V33, a thirty-fourth via V34, and a thirty-fifth via V35.

In an exemplary embodiment, an orthographic projection of the thirty-first via V31 on the base substrate is located within a range of an orthographic projection of the third connection electrode 43 on the base substrate. The fifth insulating layer in the thirty-first via V31 is removed to expose a surface of the third connection electrode 43, and the thirty-first via V31 is configured such that a data signal line formed subsequently is connected to the third connection electrode 43 through the thirty-first via.

In an exemplary embodiment, an orthographic projection of the thirty-second via V32 on the base substrate is located within a range of an orthographic projection of the fourth connection electrode 44 on the base substrate. The fifth insulating layer within the thirty-second via V32 is removed to expose a surface of the fourth connection electrode 44, and the thirty-second via V32 is configured such that the first power supply line formed subsequently is connected to the fourth connection electrode 44 through the thirty-second via.

In an exemplary embodiment, an orthographic projection of the thirty-third via V33 on the base substrate is located within a range of an orthographic projection of the fifth connection electrode 45 on the base substrate. The fifth insulating layer within the thirty-third via V33 is removed to expose a surface of the fifth connection electrode 45, and the thirty-third via V33 is configured such that an anode connection electrode formed subsequently is connected to the fifth connection electrode 45 through the thirty-third via.

In an exemplary embodiment, an orthographic projection of the thirty-fourth via V34 on the base substrate is within a range of an orthographic projection of the first reference connection block 91-1 of the first reference signal line 91 on the base substrate. The fifth insulating layer within the thirty-fourth via V34 is removed to expose a surface of the first reference connection block 91-1, and the thirty-fourth via V34 is configured such that a reference signal connection line formed subsequently is connected to the first reference connection block 91-1 through the thirty-fourth via.

In an exemplary embodiment, an orthographic projection of the thirty-fifth via V35 on the base substrate is within a range of an orthographic projection of the first power supply connection block 68-1 of the first power supply connection line 68 on the base substrate. The fifth insulating layer within the thirty-fifth via V35 is removed to expose a surface of the first power supply connection block 68-1, and the thirty-fifth via V35 is configured such that a first power supply line formed subsequently is connected to the first power supply connection block 68-1 through the thirty-fifth via.

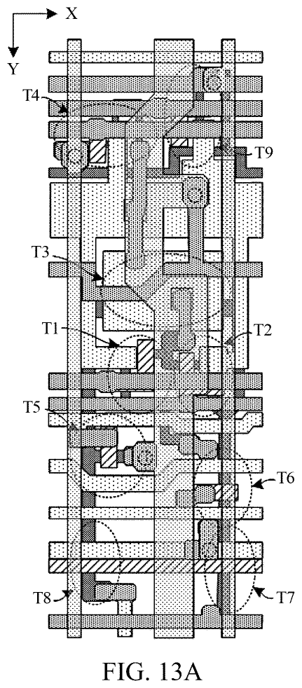

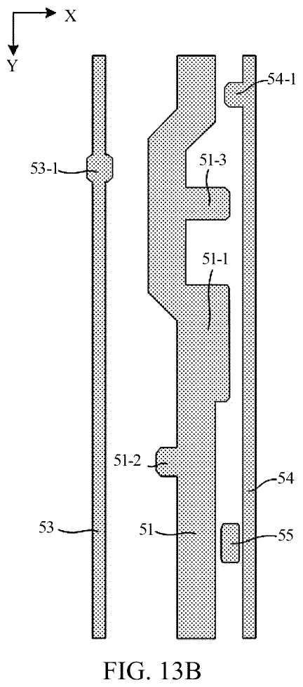

(17) Forming a pattern of a fourth conductive layer. In an exemplary embodiment, forming the pattern of the fourth conductive layer may include: depositing a fourth conductive thin film on the base substrate on which the aforementioned patterns are formed, and patterning the fourth conductive thin film by a patterning process to form the fourth conductive layer provided on the fifth insulating layer, as shown in FIG. 13A and FIG. 13B, FIG. 13B being a schematic diagram of the fourth conductive layer in FIG. 13A. In an exemplary embodiment, the fourth conductive layer may be referred to as a second source-drain metal (SD2) layer.

In an exemplary embodiment, the pattern of the fourth conductive layer in each of the plurality of circuit units in the display substrate may include a first power supply line 51, a data signal line 53, a reference signal connection line 54, and an anode connection electrode 55.

In an exemplary embodiment, the first power supply line 51, the data signal line 53, and the reference signal connection line 54 may each have a straight line shape or a bend line shape in which a main body portion extends in the second direction Y. The first power supply line 51 may be located on a side of the data signal line 53 in the first direction X, and the reference signal connection line 54 may be located on a side of the first power supply line 51 in the first direction X, that is, the first power supply line 51 may be located between the data signal line 53 and the reference signal connection line 54.

In an exemplary embodiment, the first power supply line 51 may have a bend line shape in which a main body portion extends in the second direction Y, and a side of the first power supply line 51 close to the reference signal connection line 54 is provided with a power supply shield electrode 51-1. A first end of the power supply shield electrode 51-1 is connected to the first power supply line 51, and a second end of the power supply shield electrode 51-1 extends in a direction towards the reference signal connection line 54. The power supply shield electrode 51-1 may have a rectangular shape, and an orthographic projection of the power supply shield electrode 51-1 on the base substrate at least partially overlaps with an orthographic projection of the first connection electrode 41 on the base substrate. Because the first connecting electrode 41 serves as the first node N1 in the pixel driving circuit, the power supply shield electrode 51-1 at a constant voltage may effectively shield the influence of other signals in the pixel driving circuit on the first node N1, thereby preventing other signals (such as data voltage jump) from affecting a potential of the first node N1 in the pixel driving circuit and improving the display effect.

In an exemplary embodiment, the first power supply line 51 and the power supply shield electrode 51-1 may be of an interconnected integral structure.

In an exemplary embodiment, an orthographic projection of the power supply shield electrode 51-1 on the base substrate may include an orthographic projection of the first connection electrode 41 on the base substrate.

In an exemplary embodiment, a side of the first power supply line 51 close to the data signal line 53 is provided with a first connection electrode block 51-2, a first end of the first connection electrode block 51-2 is connected to the first power supply line 51, and a second end of the first connection electrode block 51-2 extends in a direction towards the data signal line 53. The first connection electrode block 51-2 may be connected to the fourth connection electrode 44 through the thirty-second via V32. Because the fourth connection electrode 44 is connected to the first region of the fifth active layer through a via, it is achieved that the first power supply line 51 writes a first power supply signal to the first electrode of the fifth transistor T5.

In an exemplary embodiment, a side of the first power supply line 51 close to the reference signal connection line 54 is provided with a second connection electrode block 51-3, a first end of the second connection electrode block 51-3 is connected to the first power supply line 51, and a second end of the second connection electrode block 51-3 extends in a direction towards the reference signal connection line 54. The second connection electrode block 51-3 may be connected to the first power supply connection block 68-1 through the thirty-fifth via V35. Because the first power supply connecting block 68-1 is connected to the first power supply connection line 68, it is achieved that the first power supply connection line 68 in which a main body portion extends in the first direction X, and the first power supply line 51 in which a main body portion extends in the second direction Y, are connected to each other, so that the first power supply line 51 and the first power supply connection line 68 form a mesh structure for transmitting a power supply signal on the display substrate, which can not only effectively reduce a resistance of the first power supply line 51 and reduce a voltage drop of the first power supply signal, but also effectively improve uniformity of the first power supply signal in the display substrate, and effectively improve the display uniformity, thereby improving the display performance and display quality.

In an exemplary embodiment, an orthographic projection of the first power supply line 51 on the base substrate at least partially overlaps with an orthographic projection of the second connection electrode 42 on the base substrate. Because the second connection electrode 42 serves as the fifth node N5 in the pixel driving circuit, the first power supply line 51 at a constant voltage may effectively shield the influence of other signals in the pixel driving circuit on the fifth node N5, and avoid the influence of other signals on a potential at the fifth node N5 in the pixel driving circuit, thereby improving the display effect.

In an exemplary embodiment, the first power supply line 51 may be of an unequal width design, and the first power supply line 51 with the unequal width design may not only facilitate a layout of a pixel structure, but also reduce a parasitic capacitance between the first power supply line and a data signal line.

In an exemplary embodiment, the data signal line 53 may have a straight line shape in which a main body portion extends in the second direction Y. The data signal line 53 is provided with a data signal connection block 53-1, a first end of the data signal connection block 53-1 is connected to the data signal line 53, and a second end of the data signal connection block 53-1 extends toward the first end, the first direction X and a direction opposite to the first direction X of the data signal line 53. The data signal connection block 53-1 is connected to the third connection electrode 43 through the thirty-first via V31. Because the third connection electrode 43 is connected to the first region of the fourth active layer through a via, it is achieved that the data signal line 53 writes a data signal to the first electrode of the fourth transistor T4.

In an exemplary embodiment, the reference signal connection line 54 may have a straight line in which a main body portion extends in the second direction Y. The reference signal connection line 54 is provided with a reference signal connecting block 54-1, a first end of the reference signal connecting block 54-1 is connected to the reference signal connection line 54, and a second end of the reference signal connecting block 54-1 extends in a direction towards the first power supply line 51. The reference signal connecting block 54-1 may be connected to the first reference connecting block 91-1 through the thirty-fourth via V34. Because the first reference connection block 91-1 is connected to the first reference signal line 91, it is achieved that the first reference signal line 91 in which a main body portion extends in the first direction X, and the reference signal connection line 54 in which a main body portion extends in the second direction Y, are connected to each other, so that the first reference signal line 91 and the reference signal connection line 54 form a mesh structure for transmitting a first reference signal on the display substrate, which can not only effectively reduce a resistance of the first reference signal line and reduce a voltage drop of the first reference signal, but also effectively improve uniformity of the first reference signal in the display substrate, and effectively improve the display uniformity, thereby improving the display performance and display quality.

In an exemplary embodiment, the anode connection electrode 55 may have a rectangular shape, and the anode connection electrode 55 is connected to the fifth connection electrode 45 through the thirty-third via V33. Because the fifth connection electrode 45 is connected to the second region of the sixth active layer (i.e., the second region of the seventh active layer) through a via, it is achieved that the anode connection electrode 55 is connected to the second electrode of the sixth transistor T6 and the second electrode of the seventh transistor T7. In an exemplary embodiment, the anode connection electrode 55 is configured to be connected to an anode formed subsequently, so that the pixel driving circuit may drive a light emitting device.

In an exemplary embodiment, an orthographic projection of the anode connection electrode 55 on the base substrate at least partially overlaps with an orthographic projection of a anode repair line 33 on the base substrate.

In an exemplary embodiment, the first power supply connection line 68 of the third conductive layer may be provided in each unit row, the first power supply line 51 of the fourth conductive layer may be provided in each unit column, and a plurality of first power supply lines 51 are respectively connected to a plurality of first power supply connection lines 68 to form a mesh structure for transmitting a power supply signal.

In an exemplary embodiment, the first reference signal line 91 of the third conductive layer may be provided in each unit row, the reference signal connection line 54 of the fourth conductive layer may be provided in each unit column, and a plurality of first reference signal lines 91 are respectively connected to a plurality of reference signal connection lines 54 to form a mesh structure for transmitting a first reference signal.

A subsequent preparation process may include forming a pattern of a first planarization layer. The first planarization layer is provided with a plurality of anode vias, and an orthographic projection of an anode via on the base substrate is within a range of an orthographic projection of the anode connection electrode on the base substrate. The first planarization layer within the anode via is removed to expose a surface of the anode connection electrode, and the anode via is configured such that an anode formed subsequently is connected to the anode connection electrode through the anode via.

So far, the driving circuit layer in this embodiment is prepared on the base substrate. In an exemplary embodiment, after preparation of the driving circuit layer is completed, a light emitting structure layer and an encapsulation structure layer may be sequentially prepared on the driving circuit layer, which will not be repeated herein.

In the embodiment of the present disclosure, by providing the first shield electrode, the second shield electrode, the third shield electrode and the fourth shield electrode, the influence of data voltage jump on the first transistor T1, the second transistor T2, the fourth transistor T4, the ninth transistor T9 and the fifth node N5 may be shielded, thus avoiding the influence of data voltage jump on the normal operation of the pixel driving circuit, and improving the display effect.

In the embodiment of the present disclosure, by providing the power supply shield electrode, the power supply shield electrode may effectively shield the influence of other signals in the pixel driving circuit on the first node N1, thus avoiding the influence of other signals on the potential of the first node N1 of the pixel driving circuit and improving the display effect.

In the embodiment of the present disclosure, by connecting the first power supply connection line 68 in which a main body portion extends in the first direction X, to the first power supply line 51 in which a main body portion extends in the second direction Y, a high-voltage power supply grid structure with a mesh communication structure is formed on the display substrate.

The preparation process in the present disclosure may be compatible well with an existing preparation process, is simple in process implementation, is easy to implement, and has a high production efficiency, a low production cost, and a high yield.

In an exemplary embodiment, the display substrate according to the present disclosure may be applied to a display device with a pixel driving circuit, such as an OLED, a quantum dot display (QLED), a light emitting diode display (such as Micro LED or Mini LED), or a Quantum Dot Light Emitting Diode display (QDLED), which is not limited here in the present disclosure.

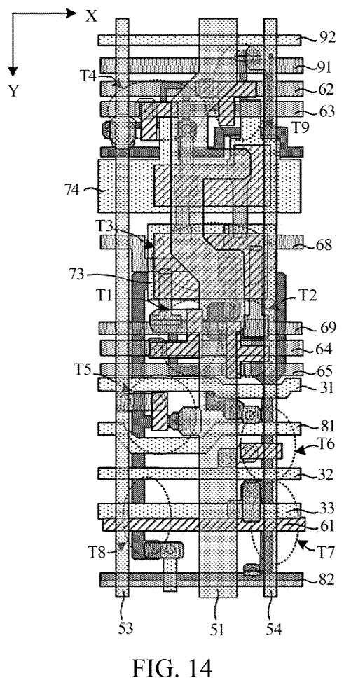

FIG. 14 is a schematic diagram of a planar structure of another display substrate according to an exemplary embodiment of the present disclosure, illustrating a structure of a pixel driving circuit in one circuit unit in a display substrate. As shown in FIG. 14, a structure of the pixel driving circuit of the present exemplary embodiment is substantially the same as that of the foregoing embodiment, except that the first shield electrode 36 and the second shield electrode 37 of the present embodiment are provided in the third conductive layer, and both the first shield electrode 36 and the second shield electrode 37 are connected to the first power supply connection line 68, and an orthographic projection of the first shield electrode 36 on the base substrate at least partially overlaps with an orthographic projection of a node between two gate electrodes of the first transistor T1 on the base substrate; and an orthographic projection of the second shield electrode 37 on the base substrate at least partially overlaps with an orthographic projection of a node between two gate electrodes of the second transistor T2 on the base substrate.

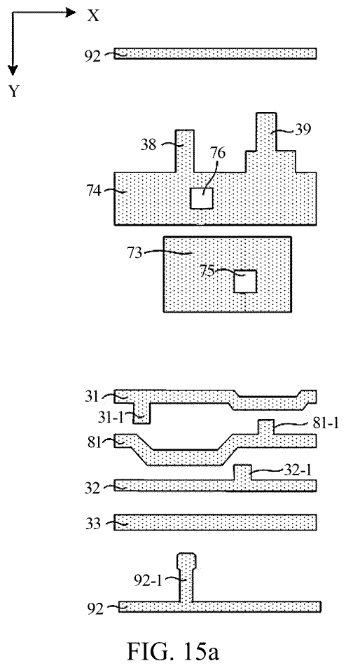

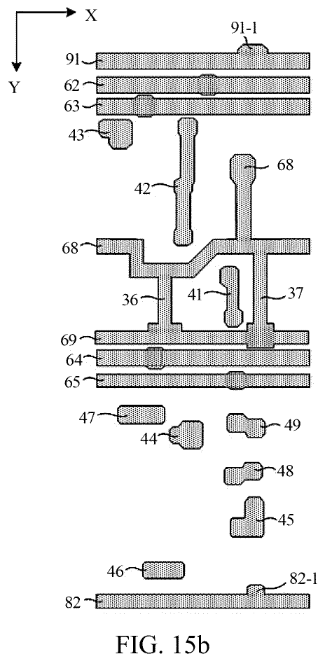

FIG. 15a is a schematic diagram of the second conductive layer in FIG. 14; and FIG. 15b is a schematic diagram of the third conductive layer in FIG. 14. In an exemplary embodiment, as shown in FIGS. 14 and 15a, a side of the fourth electrode plate 74 close to the first light emitting signal line 31 is not provided with a first shield electrode 36 and a second shield electrode 37, and an edge of the side of the fourth electrode plate 74 close to the first light emitting signal line 31 has a straight line shape and is located on a side of the third electrode plate 73 away from the first light emitting signal line 31.

In an exemplary embodiment, as shown in FIGS. 14 and 15b, the first power supply connection line 68 may have a bend line shape in which a main body portion extends in the first direction X. The first power supply connection line 68 may be located on a side of the fourth electrode plate 74 in the second direction Y, and an orthographic projection of the first power supply connection line 68 on the base substrate at least partially overlaps with an orthographic projection of the third electrode plate 73 on the base substrate. A side of the first power supply connection line 68 close to the fourth scan signal line 64 is provided with a first shield electrode 36. The first shield electrode 36 may have a line shape in which a main body portion extends in the second direction Y. A first end of the first shield electrode 36 is connected to the first power supply connection line 68 and a second end of the first shield electrode 36 extends toward the fourth scan signal line 64. An orthographic projection of the first shield electrode 36 on the base substrate at least partially overlaps with an orthographic projection of the first active layer between two gate electrodes of the first transistor T1 on the base substrate. In an exemplary embodiment, the first shield electrode 36 is configured to shield the influence of the data voltage jump on the first transistor T1, and prevent the data voltage jump from affecting the normal operation of the pixel driving circuit, thereby improving the display effect.

In an exemplary implementation, the first power supply connection line 68 and the first shield electrode 36 may be of an interconnected integral structure.

In an exemplary embodiment, as shown in FIGS. 14 and 15b, a side of the first power supply connection line 68 close to the fourth scan signal line 64 is provided with a second shield electrode 37. The second shield electrode 37 may have a line shape in which a main body portion extends in the second direction Y. A first end of the second shield electrode 37 is connected to the first power supply connection line 68 and a second end of the second shield electrode 37 extends toward the fourth scan signal line 64. An orthographic projection of the second shield electrode 37 on the base substrate at least partially overlaps with an orthographic projection of the first active layer between two gate electrodes of the second transistor T2 on the base substrate. In an exemplary embodiment, the second shield electrode 37 is configured to shield the influence of the data voltage jump on the second transistor T2, and prevent the data voltage jump from affecting the normal operation of the pixel driving circuit, thereby improving the display effect.

In an exemplary embodiment, the first power supply connection line 68 and the second shield electrode 37 may be of an interconnected integral structure.

In an exemplary embodiment, at least one circuit unit of the present exemplary embodiment further includes a shield connection line 69 which may be located in the third conductive layer. The shield connection line 69 may have a line shape in which a main body portion extends in the first direction X. The shield connection line 69 may be located between the first power supply connection line 68 and the fourth scan signal line 64. The shield connection line 69 is connected to the second end of the first shield electrode 36, and the shield connection line 69 is connected to the first power supply connection line 68 through the first shield electrode 36.

In an exemplary embodiment, the shield connection line 69 and the first shield electrode 36 may be an interconnected integral structure.

In an exemplary embodiment, the shield connection line 69 of the present exemplary embodiment may be connected to the second end of the second shield electrode 37, and the shield connection line 69 is connected to the first power supply connection line 68 through the second shield electrode 37.

In an exemplary embodiment, the shield connection line 69 and the second shield electrode 37 may be of an interconnected integral structure.

In the embodiment of the present disclosure, by connecting the shielding connection line to the first power supply connection line, and connecting the first power supply connection line and the first power supply line to each other, the first power supply line forms a mesh structure, for transmitting a power supply signal on the display substrate, with the first power supply connection line and the shielding connection line, respectively, which can not only effectively reduce a resistance of the first power supply line and reduce a voltage drop of the first power supply signal, but also effectively improve uniformity of the first power supply signal in the display substrate, and effectively improve the display uniformity, thereby improving the display performance and display quality.

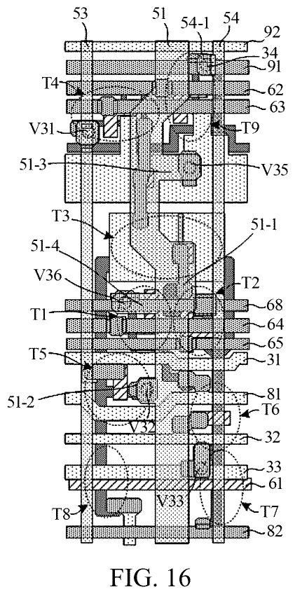

FIG. 16 is a schematic diagram of a planar structure of yet another display substrate according to an exemplary embodiment of the present disclosure, illustrating a structure of a pixel driving circuit in one circuit unit in a display substrate. As shown in FIG. 16, a structure of the pixel driving circuit of the present exemplary embodiment is substantially the same as that of the embodiment shown in FIG. 14, except that the first power supply connection line 68 of the present exemplary embodiment is provided on a side of the first connection electrode 41 in the second direction Y, and at least one circuit unit further includes a second power supply connection block 68-2.

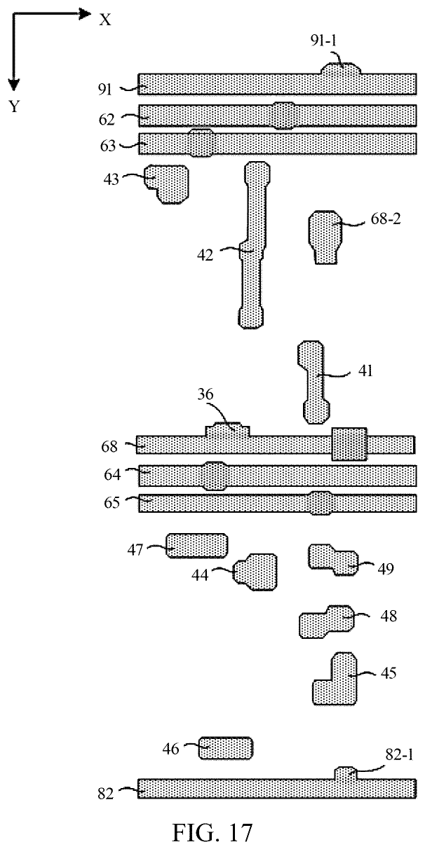

FIG. 17 is a schematic diagram of the third conductive layer in FIG. 16. In an exemplary embodiment, as shown in FIGS. 16 and 17, the at least one circuit unit further includes a second power supply connection block 68-2, which may have a block shape. The second power supply connection block 68-2 is located on a side of the third scan signal line 63 in the second direction Y, on a side of the first connection electrode 41 in a direction opposite to the second direction Y, and on a side of the second connection electrode 42 in the first direction X. The second power supply connection block 68-2 is configured, on the one hand, to be connected to the fourth electrode plate 74 through the thirteenth via V13, and on the other hand, to be connected to the first power supply line through the thirty-fifth via V35.

In an exemplary embodiment, the first power supply connection line 68 of the present exemplary embodiment may have a line shape in which a main body portion extends in the first direction X. The first power supply connection line 68 may be located on a side of the fourth scan signal line 64 in a direction opposite to the second direction Y and on a side of the first connection electrode 41 in the second direction Y, that is, the first power supply connection line 68 may be located between the fourth scan signal line 64 and the first connection electrode 41. The first power supply connection line 68 may be connected to the first power supply line 51 through the thirty-sixth via V36, thereby achieving that the first power supply connection line 68 in which a main body portion extends in the first direction X and the first power supply line 51 in which a main body portion extends in the second direction Y are connected to each other.

In an exemplary embodiment, the first shield electrode 36 may have a shape in which a main body portion is in a block shape. The first shield electrode 36 is connected to the first power supply connection line 68, and an orthographic projection of the first shield electrode 36 on the base substrate at least partially overlaps with an orthographic projection of the first active layer between two gate electrodes of the first transistor T1 on the base substrate. In an exemplary embodiment, the first shield electrode 36 is configured to shield the influence of the data voltage jump on the first transistor T1, and prevent the data voltage jump from affecting the normal operation of the pixel driving circuit, thereby improving the display effect.

In an exemplary implementation, the first power supply connection line 68 and the first shield electrode 36 may be of an interconnected integral structure.

In an exemplary embodiment, the second shield electrode 37 may have a shape in which a main body portion is in a block shape. The second shield electrode 37 is connected to the first power supply connection line 68, and an orthographic projection of the second shield electrode 37 on the base substrate at least partially overlaps with an orthographic projection of the first active layer between two gate electrodes of the second transistor T2 on the base substrate. In an exemplary embodiment, the second shield electrode 37 is configured to shield the influence of the data voltage jump on the second transistor T2, and prevent the data voltage jump from affecting the normal operation of the pixel driving circuit, thereby improving the display effect.

In an exemplary embodiment, the first power supply connection line 68 and the second shield electrode 37 may be of an interconnected integral structure.

As shown in FIGS. 16 and 17, on the display substrate, an orthographic projection of the thirty-fifth via V35 of the plurality of vias of the circuit unit on the base substrate is within a range of an orthographic projection of the second power supply connection block 68-2 on the base substrate, the fifth insulating layer in the thirty-fifth via V35 is removed to exposing a surface of the second power supply connection block 68-2, and the thirty-fifth via V35 is configured such that the first power supply line 51 is connected to the second power connection block 68-2 through the thirty-fifth via.

In an exemplary embodiment, the plurality of vias in the circuit unit of the display substrate further includes a thirty-sixth via V36. An orthographic projection of the thirty-sixth via V36 on the base substrate is within a range of an orthographic projection of the first power supply connection line 68 on the base substrate, the fifth insulating layer in the thirty-sixth via V36 is removed to expose a surface of the first power supply connection line 68, and the thirty-sixth via V36 is configured such that the first power supply line 51 is connected to the first power supply connection line 68 through the thirty-sixth via.

In an exemplary embodiment, the first power supply line 51 in the circuit unit of the display substrate may have a bend line shape in which a main body portion extends in the second direction Y. A side of the first power supply line 51 close to the data signal line 53 is provided with a third connection electrode block 51-4, a first end of the third connection electrode block 51-4 is connected to the first power supply line 51, and a second end of the third connection electrode block 51-4 extends in a direction towards the data signal line 53. The third connection electrode block 51-4 may be connected to the first power supply connection line 68 through the thirty-sixth via V36. Because the third connection electrode block 51-4 is connected to the first power supply connection line 68, it is achieved that the first power supply connection line 68 in which a main body portion extends in the first direction X, and the first power supply line 51 in which a main body portion extends in the second direction Y, are connected to each other, so that the first power supply line 51 and the first power supply connection line 68 form a mesh structure for transmitting a power supply signal on the display substrate, which can not only effectively reduce a resistance of the first power supply line 51 and reduce a voltage drop of the first power supply signal, but also effectively improve the uniformity of the first power supply signal in the display substrate, and effectively improve the display uniformity, thereby improving the display performance and display quality.

In some embodiments, the first power supply connection line in the present exemplary embodiment may be connected to a constant voltage line other than the first power supply line through a via, for example, a second power supply line (VSS), a reference signal connection line, an initial signal line, or the like.

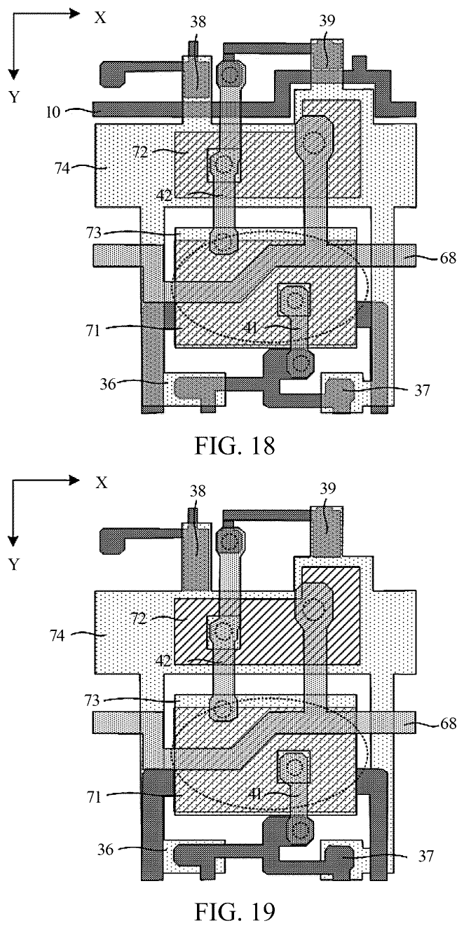

FIG. 18 is an enlarged view of regions of a first storage capacitor and a second storage capacitor in yet another display substrate according to an exemplary embodiment of the present disclosure. As shown in FIG. 18, a structure of the pixel driving circuit of the present exemplary embodiment is substantially the same as that of the embodiment shown in FIG. 5, except that an area of an orthographic projection of the semiconductor layer between two gate electrodes of the fourth transistor T4 on the base substrate in the display substrate of the present exemplary embodiment is larger than an area of an orthographic projection of the semiconductor layer between two gate electrodes of the fourth transistor T4 on the base substrate in the display substrate of the embodiment shown in FIG. 5. An area of an orthographic projection of the semiconductor layer between two gate electrodes of the ninth transistor T9 on the base substrate in the display substrate of the present exemplary embodiment is larger than an area of an orthographic projection of the semiconductor layer between two gate electrodes of the ninth transistor T9 on the base substrate in the display substrate of the embodiment shown in FIG. 5.

In an exemplary embodiment, the area of the orthographic projection of the semiconductor layer between the two gate electrodes of the fourth transistor T4 on the base substrate is more than 3 times, for example, 5 times, 7 times, 10 times, 15 times, 20 times, or the like, an area of an orthographic projection of the fourth active layer of the fourth transistor T4 on the base substrate.

In an exemplary embodiment, the area of the orthographic projection of the semiconductor layer between the two gate electrodes of the ninth transistor T9 on the base substrate is more than 3 times, for example, 5 times, 7 times, 10 times, 15 times, 20 times, or the like, an area of an orthographic projection of the ninth active layer of the ninth transistor T9 on the base substrate.

In an exemplary embodiment, a length of the semiconductor layer between the two gate electrodes of the fourth transistor T4 in the first direction X in the display substrate of the present exemplary embodiment is larger than a length of the semiconductor layer between the two gate electrodes of the fourth transistor T4 in the first direction X in the display substrate of the embodiment shown in FIG. 5; and a length of the semiconductor layer between the two gate electrodes of the fourth transistor T4 in the second direction Y in the display substrate of the present exemplary embodiment is larger than a length of the semiconductor layer between the two gate electrodes of the fourth transistor T4 in the second direction Y in the display substrate of the embodiment shown in FIG. 5.

In an exemplary embodiment, a length of the semiconductor layer between the two gate electrodes of the ninth transistor T9 in the first direction X in the display substrate of the present exemplary embodiment is larger than a length of the semiconductor layer between the two gate electrodes of the ninth transistor T9 in the first direction X in the display substrate of the embodiment shown in FIG. 5; and a length of the semiconductor layer between the two gate electrodes of the ninth transistor T9 in the second direction Y in the display substrate of the present exemplary embodiment is larger than a length of the semiconductor layer between the two gate electrodes of the ninth transistor T9 in the second direction Y in the display substrate of the embodiment shown in FIG. 5.

In the display substrate of the present exemplary embodiment, leakage current of the fourth transistor T4 and the ninth transistor T9 is reduced by increasing the area of the orthographic projection of the semiconductor layer between the two gate electrodes of the fourth transistor T4 on the base substrate and the area of the orthographic projection of the semiconductor layer between the two gate electrodes of the ninth transistor T9 on the base substrate.

FIG. 19 is an enlarged view of regions of a first storage capacitor and a second storage capacitor in yet another display substrate according to an exemplary embodiment of the present disclosure. As shown in FIG. 19, a structure of the pixel driving circuit of the present exemplary embodiment is substantially the same as that of the embodiment shown in FIG. 18, except that the semiconductor layer in the display substrate of the present exemplary embodiment is not provided with a first active connection line, and an area of an orthographic projection of the semiconductor layer between two gate electrodes of the fourth transistor T4 on the base substrate in the display substrate of the present exemplary embodiment is larger than an area of an orthographic projection of the semiconductor layer between two gate electrodes of the fourth transistor T4 on the base substrate in the display substrate of the embodiment shown in FIG. 18. An area of an orthographic projection of the semiconductor layer between two gate electrodes of the ninth transistor T9 on the base substrate in the display substrate of the present exemplary embodiment is larger than an area of an orthographic projection of the semiconductor layer between two gate electrodes of the ninth transistor T9 on the base substrate in the display substrate of the embodiment shown in FIG. 18.

In the present exemplary embodiment, because no first active connection line is provided, the semiconductor layer between the two gate electrodes of the fourth transistor T4 and the semiconductor layer between the two gate electrodes of the ninth transistor T9 in the display substrate of the present exemplary embodiment may extend in the second direction Y, thereby increasing areas of orthographic projections of the semiconductor layers on the base substrate. A length of the semiconductor layer between the two gate electrodes of the fourth transistor T4 in the second direction Y in the display substrate of the present exemplary embodiment is larger than a length of the semiconductor layer between the two gate electrodes of the fourth transistor T4 in the second direction Y in the display substrate of the embodiment shown in FIG. 18. A length of the semiconductor layer between the two gate electrodes of the ninth transistor T9 in the second direction Y in the display substrate of the present exemplary embodiment is larger than a length of the semiconductor layer between the two gate electrodes of the ninth transistor T9 in the second direction Y in the display substrate of the embodiment shown in FIG. 18.

In the display substrate of the present exemplary embodiment, leakage current of the fourth transistor T4 and the ninth transistor T9 is reduced by increasing the area of the orthographic projection of the semiconductor layer between the two gate electrodes of the fourth transistor T4 on the base substrate and the area of the orthographic projection of the semiconductor layer between the two gate electrodes of the ninth transistor T9 on the base substrate.

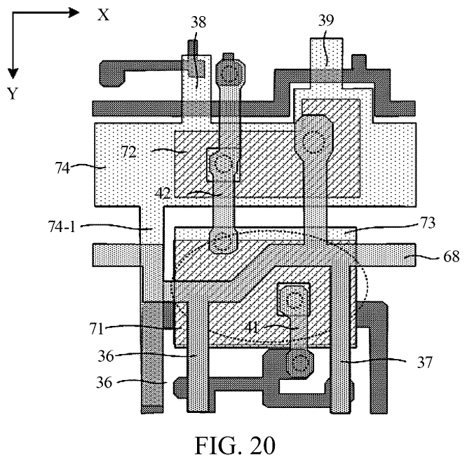

FIG. 20 is an enlarged view of regions of a first storage capacitor and a second storage capacitor in yet another display substrate according to an exemplary embodiment of the present disclosure. As shown in FIG. 20, a structure of the pixel driving circuit of the present exemplary embodiment is substantially the same as that of the embodiment shown in FIG. 14, except that the pattern of the second conductive layer in the display substrate of the present exemplary embodiment further includes a fifth shield electrode 74-1 connected to the fourth electrode plate 74, and an orthographic projection of the fifth shield electrode 74-1 on the base substrate at least partially overlaps with an orthographic projection of the data signal line 53 on the base substrate. The fifth shield electrode 74-1 is configured to shield a signal of the data signal line 53 and ensure uniform load of the data signal line 53.

In an exemplary embodiment, the first shield electrode 36 and the second shield electrode 37 of the present embodiment are provided in the third conductive layer, and both the first shield electrode 36 and the second shield electrode 37 are connected to the first power supply connection line 68, and an orthographic projection of the first shield electrode 36 on the base substrate at least partially overlaps with an orthographic projection of a node between two gate electrodes of the first transistor T1 on the base substrate; and an orthographic projection of the second shield electrode 37 on the base substrate at least partially overlaps with an orthographic projection of a node between two gate electrodes of the second transistor T2 on the base substrate.

In an exemplary embodiment, the fifth shield electrode 74-1 is located on a side of the fourth electrode plate 74 in the second direction Y. The fifth shield electrode 74-1 may have a strip shape extending in the second direction Y. A first end of the fifth shield electrode 74-1 is connected to the fourth electrode plate 74, and a second end of the fifth shield electrode 74-1 extends in the second direction Y.

In an exemplary embodiment, the fourth electrode plate 74 and the fifth shield electrode 74-1 may be of an interconnected integral structure.

In some embodiments, an orthographic projection of the fifth shield electrode on the base substrate may not overlap with an orthographic projection of the data signal line on the base substrate.

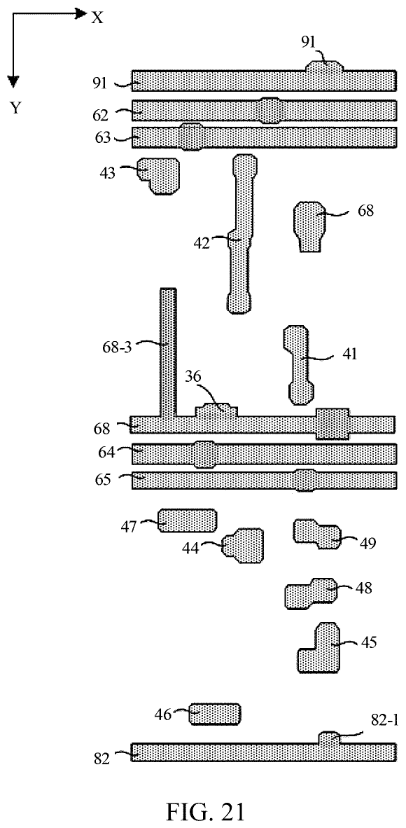

FIG. 21 is a schematic diagram of a third conductive layer in yet another display substrate according to an exemplary embodiment of the present disclosure. As shown in FIG. 21, a structure of the pixel driving circuit of the present exemplary embodiment is substantially the same as that of the embodiment shown in FIG. 16, except that the third conductive layer in the display substrate of the present exemplary embodiment further includes a sixth shield electrode 68-3 connected to the first power supply connection line 68, and an orthographic projection of the sixth shield electrode 68-3 on the base substrate at least partially overlaps with an orthographic projection of the data signal line 53 on the base substrate. The sixth shield electrode 68-3 is configured to shield a signal of the data signal line 53 and ensure uniform load of the data signal line 53.

In an exemplary embodiment, the sixth shield electrode 68-3 is located on a side of the first power supply connection line 68 in a direction opposite to the second direction Y. The sixth shield electrode 68-3 may have a strip shape extending in a direction opposite to the second direction Y. A first end of the sixth shield electrode 68-3 is connected to the first power supply connection line 68, and a second end of the sixth shield electrode 68-3 extends in a direction opposite to the second direction Y.

In an exemplary embodiment, the first power supply connection line 68 and the sixth shield electrode 68-3 may be of an interconnected integral structure.

In an exemplary embodiment, an orthographic projection of the sixth shield electrode on the base substrate is located in an orthographic projection of the data signal line on the base substrate, thereby avoiding the influence of the sixth shield electrode on the light transmittance of the display substrate.

In the exemplary embodiment, a length of the sixth shield electrode in the first direction X is larger than a length of the data signal line 53 in the first direction X, thereby ensuring the flatness of the data signal line 53 formed subsequently.

The present disclosure further provides a preparation method for a display substrate, for preparing the display substrate according to the foregoing embodiments.

In an exemplary embodiment, the preparation method for the display substrate may include: forming a driving circuit layer on a base substrate. The driving circuit layer at least includes a plurality of circuit units, and at least one circuit unit includes a pixel driving circuit including a first storage capacitor, a second storage capacitor, at least one shield electrode, and at least one double-gate structured transistor. The first storage capacitor at least includes a first electrode plate and a third electrode plate, and an orthographic projection of the first electrode plate on the base substrate at least partially overlaps with an orthographic projection of the third electrode plate on the base substrate. The second storage capacitor at least includes a second electrode plate and a fourth electrode plate, and an orthographic projection of the second electrode plate on the base substrate at least partially overlaps with an orthographic projection of the fourth electrode plate on the base substrate. The second electrode plate is connected to the third electrode plate, and the fourth electrode plate is connected to a first power supply line. An orthographic projection of a shield electrode on the base substrate at least partially overlaps with an orthographic projection of a node between two gate electrodes of a double-gate structured transistor on the base substrate.

The present disclosure further provides a display device, including the aforementioned display substrate. The display device may be any product or component with a display function, such as a mobile phone, a tablet computer, a television, a display, a laptop computer, a digital photo frame, or a navigator, which is not limited in the embodiments of the present invention.

Although implementation disclosed in the present disclosure are described as above, the described contents are only implementation which are used for facilitating understanding of the present disclosure, but are not intended to limit the present invention. Any skilled person in the art to which the present disclosure pertains may make any modification and variation in a form and details of implementation without departing from the spirit and scope of the present disclosure. However, the patent protection scope of the present invention should be subject to the scope defined in the appended claims.

1. A display substrate, comprising a driving circuit layer provided on a base substrate, wherein: the driving circuit layer at least comprises a plurality of circuit units, and at least one circuit unit comprises a pixel driving circuit comprising a first storage capacitor, a second storage capacitor, at least one shield electrode, and at least one double-gate structured transistor; the first storage capacitor at least comprises a first electrode plate and a third electrode plate, and an orthographic projection of the first electrode plate on the base substrate at least partially overlaps with an orthographic projection of the third electrode plate on the base substrate; the second storage capacitor at least comprises a second electrode plate and a fourth electrode plate, and an orthographic projection of the second electrode plate on the base substrate is at least partially overlapped with an orthographic projection of the fourth electrode plate on the base substrate; the second electrode plate is connected to the third electrode plate, and the fourth electrode plate is connected to a first power supply line; and an orthographic projection of the shield electrode on the base substrate is at least partially overlapped with an orthographic projection of a node between two gate electrodes of the double-gate structured transistor on the base substrate.

2. The display substrate according to claim 1, wherein the at least one double-gate structured transistor comprises an initialization transistor, a first electrode of the initialization transistor is connected to a first initial signal line, and a second electrode of the initialization transistor is connected to the first electrode plate of the first storage capacitor; the at least one shield electrode comprises a first shield electrode connected to the fourth electrode plate, and an orthographic projection of the first shield electrode on the base substrate is at least partially overlapped with an orthographic projection of a node between two gate electrodes of the initialization transistor on the base substrate.

3. The display substrate according to claim 2, wherein the fourth electrode plate and the first shield electrode are of an integral structure.

4. The display substrate according to claim 2, wherein the first shield electrode comprises a first extension segment and a first shield segment; the first extension segment has a strip shape extending in a second direction, a first end of the first extension segment is connected to the fourth electrode plate, and a second end of the first extension segment is connected to a first end of the first shield segment; the first shield segment has a strip shape extending in a first direction, the first end of the first shield segment is connected to the second end of the first extension segment, and a second end of the first shield segment is extended in the first direction; an orthographic projection of the first shield segment on the base substrate is at least partially overlapped with the orthographic projection of the node between the two gate electrodes of the initialization transistor on the base substrate; and the first direction is intersected with the second direction.

5. The display substrate according to claim 1, wherein the at least one circuit unit further comprises at least one first power supply connection line extending in a first direction, the first power supply line has a line shape extending in a second direction, and the first direction is intersected with the second direction; and the first power supply line is connected to the first power supply connection line to form a mesh structure for transmitting a first power supply signal.

6. The display substrate according to claim 5, wherein the at least one double-gate structured transistor comprises an initialization transistor, a first electrode of the initialization transistor is connected to a first initial signal line, and a second electrode of the initialization transistor is connected to the first electrode plate of the first storage capacitor; the at least one shield electrode comprises a first shield electrode connected to the first power supply connection line; and an orthographic projection of the first shield electrode on the base substrate is at least partially overlapped with an orthographic projection of a node between two gate electrodes of the initialization transistor on the base substrate.

7. The display substrate according to claim 6, wherein the first power supply connection line and the first shield electrode are of an integral structure.

8. The display substrate according to claim 5, wherein the at least one circuit unit further comprises a shield connection line connected to the first power supply connection line; the at least one double-gate structured transistor comprises an initialization transistor, a first electrode of the initialization transistor is connected to a first initial signal line, and a second electrode of the initialization transistor is connected to the first electrode plate of the first storage capacitor; the at least one shield electrode comprises a first shield electrode connected to the shield connection line; and an orthographic projection of the first shield electrode on the base substrate is at least partially overlapped with an orthographic projection of a node between two gate electrodes of the initialization transistor on the base substrate.

9. The display substrate according to claim 2, wherein the at least one double-gate structured transistor comprises a compensation transistor, and a first electrode of the compensation transistor is connected to the first electrode plate of the first storage capacitor; the at least one shield electrode comprises a second shield electrode connected to the fourth electrode plate; and an orthographic projection of the second shield electrode on the base substrate is at least partially overlapped with an orthographic projection of a node between two gate electrodes of the compensation transistor on the base substrate.

10. The display substrate according to claim 9, wherein the fourth electrode plate and the second shield electrode are of an integral structure.

11. The display substrate according to claim 9, wherein the second shield electrode comprises a second extension segment and a second shield segment; the second extension segment has a strip shape extending in a second direction, a first end of the second extension segment is connected to the fourth electrode plate, and a second end of the second extension segment is connected to a first end of the second shield segment; the second shield segment has a strip shape extending in a first direction, the first end of the second shield segment is connected to the second end of the second extension segment, and a second end of the second shield segment is extended in a direction opposite the first direction; an orthographic projection of the second shield segment on the base substrate is at least partially overlapped with the orthographic projection of the node between the two gate electrodes of the compensation transistor on the base substrate; and the first direction is intersected with the second direction.

12. The display substrate according to claim 5, wherein the at least one double-gate structured transistor comprises a compensation transistor, and a first electrode of the compensation transistor is connected to the first electrode plate of the first storage capacitor; the at least one shield electrode comprises a second shield electrode connected to the first power supply connection line; and an orthographic projection of the second shield electrode on the base substrate is at least partially overlapped with an orthographic projection of a node between two gate electrodes of the compensation transistor on the base substrate.

13. The display substrate according to claim 12, wherein the first power supply connection line and the second shield electrode are of an integral structure.

14. The display substrate according to claim 5, wherein the at least one circuit unit further comprises a shield connection line connected to the first power supply connection line; the at least one double-gate structured transistor comprises a compensation transistor, and a first electrode of the compensation transistor is connected to the first electrode plate of the first storage capacitor; the at least one shield electrode comprises a second shield electrode connected to the shield connection line; and an orthographic projection of the second shield electrode on the base substrate is at least partially overlapped with an orthographic projection of a node between two gate electrodes of the compensation transistor on the base substrate.

15. The display substrate according to claim 1, wherein the at least one double-gate structured transistor comprises a data writing transistor, a first electrode of the data writing transistor is connected to a data signal line, and a second electrode of the data writing transistor is connected to the second electrode plate of the second storage capacitor; the at least one shield electrode comprises a third shield electrode connected to the fourth electrode plate; and an orthographic projection of the third shield electrode on the base substrate is at least partially overlapped with an orthographic projection of a node between two gate electrodes of the data writing transistor on the base substrate.

16. The display substrate according to claim 15, wherein the fourth electrode plate and the third shield electrode are of an integral structure.

17. The display substrate according to claim 1, wherein the at least one double-gate structured transistor comprises a reference transistor, a first electrode of the reference transistor is connected to a second reference signal line, and a second electrode of the reference transistor is connected to the second electrode plate of the second storage capacitor; the at least one shield electrode comprises a fourth shield electrode connected to the fourth electrode plate; and an orthographic projection of the fourth shield electrode on the base substrate is at least partially overlapped with an orthographic projection of a node between two gate electrodes of the reference transistor on the base substrate.

18. The display substrate according to claim 17, wherein the fourth electrode plate and the fourth shield electrode are of an integral structure.

19. A display device, comprising the display substrate according to claim 1.

20. A display substrate, comprising a driving circuit layer provided on a base substrate, wherein: the driving circuit layer at least comprises a plurality of circuit units, and at least one circuit unit comprises a pixel driving circuit comprising a first storage capacitor, a second storage capacitor, at least one shield electrode, and at least one double-gate structured transistor; the first storage capacitor at least comprises a first electrode plate and a third electrode plate, the second storage capacitor at least comprises a second electrode plate and a fourth electrode plate, and an orthographic projection of the shield electrode on the base substrate is at least partially overlapped with an orthographic projection of a node between two gate electrodes of the double-gate structured transistor on the base substrate; the at least one double-gate structured transistor comprises a first transistor to a ninth transistor; the pixel driving circuit further comprises a first node, a second node, a third node, a fourth node and a fifth node; the first node is respectively connected to a second electrode of the first transistor, a first electrode of the second transistor, a gate electrode of the third transistor and the first electrode plate of the first storage capacitor; the second node is respectively connected to a first electrode of the third transistor, a second electrode of the eighth transistor and a second electrode of the fifth transistor; the third node is respectively connected to a second electrode of the second transistor, a second electrode of the third transistor and a first electrode of the sixth transistor; the fourth node is respectively connected to a second electrode of the sixth transistor and a second electrode of the seventh transistor; the fifth node is respectively connected to a second electrode of the fourth transistor, a second electrode of the ninth transistor, the third electrode plate of the first storage capacitor and the second electrode plate of the second storage capacitor; and the fourth electrode plate of the second storage capacitor is connected to a first power supply line.

21. (canceled)
